(19) United States
(12) Patent Application Publication
(10) Pub. No.: US 2024/0321743 A1
(43) Pub. Date: Sep. 26, 2024

(54) SEMICONDUCTOR STORAGE DEVICE AND METHOD FOR MANUFACTURING SEMICONDUCTOR STORAGE DEVICE

(71) Applicant: Kioxia Corporation, Tokyo (JP)

(72) Inventor: Keisuke ISHIZUKA, Yokkaichi Mie (JP)

(21) Appl. No.: 18/593,582

(22) Filed: Mar. 1, 2024

(30) Foreign Application Priority Data
Mar. 20, 2023 (JP) 2023-044750

(51) Int. Cl. H01L 23/528; H10B 41/10; H10B 41/27; H10B 41/40; H10B 43/10; H10B 43/27; H10B 43/40

(52) U.S. Cl. CPC H01L 23/5283; H10B 41/10; H10B 41/27; H10B 41/40; H10B 43/10; H10B 43/27; H10B 43/40

(57) ABSTRACT

A semiconductor storage device includes a first stacked body in which first conductive layers and first insulating layers are alternately stacked in a stacking direction, a second stacked body above the first stacked body and in which second conductive layers and second insulating layers are alternately stacked in the stacking direction, a contact that extends in the first and second stacked bodies in the stacking direction and is connected to a first conductive layer. The contact has a first portion that extends in the first stacked body and is connected at a lower end portion thereof to the first conductive layer, a second portion that extends in the second stacked body and is connected to an upper end portion of the first portion, the second portion having a cross-section at a lower end portion thereof that is smaller than a cross-section at the upper end portion of the first portion.

### CROSS-REFERENCE TO RELATED APPLICATION(S)

This application is based upon and claims the benefit of priority from Japanese Patent Application No. 2023-044750, filed Mar. 20, 2023, the entire contents of which are incorporated herein by reference.

### FIELD

Embodiments described herein relate generally to a semiconductor storage device and a method for manufacturing a semiconductor storage device.

### BACKGROUND

In a semiconductor storage device such as a three-dimensional nonvolatile memory, memory cells are formed three-dimensionally in a stacked body in which a plurality of conductive layers are stacked. In order to apply voltages to these conductive layers, a plurality of contacts extending in the stacked body and connected to these conductive layers are employed. An insulating layer is disposed on the side wall of each of the plurality of contacts to prevent short circuits between the conductive layers in the stacked body.

Such an insulating layer is obtained by forming an insulating layer on the side wall and the bottom surface of the contact hole and removing the insulating layer on the bottom surface. However, when the insulating layer is removed from the bottom surface of the contact hole, a part of another configuration provided in the vicinity of the contact hole may also be removed, and in this case, a plurality of the conductive layers in the stacked body may be short-circuited.

### DESCRIPTION OF THE DRAWINGS

FIG. 1 is a sectional view showing a schematic configuration example of a semiconductor storage device according to an embodiment.

FIGS. 2AA to 2AD, FIGS. 2BA and 2BB, and FIG. 2C are sectional views showing an example of a configuration of a semiconductor storage device according to the embodiment.

FIGS. 3A to 3C are views sequentially showing a part of the procedure of the method for manufacturing a semiconductor storage device according to the embodiment.

FIGS. 4A to 4C are views sequentially showing a part of the procedure of the method for manufacturing a semiconductor storage device according to the embodiment.

FIGS. 5A to 5C are views sequentially showing a part of the procedure of the method for manufacturing a semiconductor storage device according to the embodiment.

FIGS. 6A to 6C are views sequentially showing a part of the procedure of the method for manufacturing a semiconductor storage device according to the embodiment.

FIGS. 7A to 7C are views sequentially showing a part of the procedure of the method for manufacturing a semiconductor storage device according to the embodiment.

FIGS. 8A and 8B are views sequentially showing a part of the procedure of the method for manufacturing a semiconductor storage device according to the embodiment.

FIGS. 9A and 9B are views sequentially showing a part of the procedure of the method for manufacturing a semiconductor storage device according to the embodiment.

FIGS. 10A and 10B are views sequentially showing a part of the procedure of the method for manufacturing a semiconductor storage device according to the embodiment.

FIGS. 11A and 11B are views sequentially showing a part of the procedure of the method for manufacturing a semiconductor storage device according to the embodiment.

FIGS. 12A and 12B are views sequentially showing a part of the procedure of the method for manufacturing a semiconductor storage device according to the embodiment.

FIGS. 13A and 13B are views sequentially showing a part of the procedure of the method for manufacturing a semiconductor storage device according to the embodiment.

FIGS. 14A and 14B are views sequentially showing a part of the procedure of the method for manufacturing a semiconductor storage device according to the embodiment.

FIGS. 15A and 15B are views sequentially showing a part of the procedure of the method for manufacturing a semiconductor storage device according to the embodiment.

FIGS. 16A and 16B are views sequentially showing a part of the procedure of the method for manufacturing a semiconductor storage device according to the embodiment.

FIGS. 17A and 17B are views sequentially showing a part of the procedure of the method for manufacturing a semiconductor storage device according to the embodiment.

FIGS. 18A and 18B are views sequentially showing a part of the procedure of the method for manufacturing a semiconductor storage device according to the embodiment.

FIGS. 19A and 19B are views sequentially showing a part of the procedure of the method for manufacturing a semiconductor storage device according to the embodiment.

FIGS. 20A and 20B are views sequentially showing a part of the procedure of the method for manufacturing a semiconductor storage device according to the embodiment.

FIGS. 21A and 21B are views sequentially showing a part of the procedure of the method for manufacturing a semiconductor storage device according to the embodiment.

FIGS. 22A and 22B are views sequentially showing a part of the procedure of the method for manufacturing a semiconductor storage device according to the embodiment.

FIGS. 23A and 23B are views sequentially showing a part of the procedure of the method for manufacturing a semiconductor storage device according to the embodiment.

FIGS. 24A and 24B are views sequentially showing a part of the procedure of the method for manufacturing a semiconductor storage device according to the embodiment.

FIGS. 25A and 25B are sectional views along the X direction showing a state in which the insulating layer is removed from the bottom surface of the contact hole according to the embodiment and the comparative example.

FIGS. 26A to 26H are sectional views along the X direction showing a part of the procedure of the method for manufacturing a semiconductor storage device according to another modification example of the embodiment.

FIG. 27 is a sectional view along the X direction showing an example of a configuration of a semiconductor storage device according to another modification example of the embodiment.

FIGS. 28A to 28C are sectional views along the X direction sequentially showing a part of the procedure of the method for manufacturing a semiconductor storage device according to another modification example of the embodiment.

FIGS. 29A to 29C are sectional views along the X direction sequentially showing a part of the procedure of the method for manufacturing a semiconductor storage device according to another modification example of the embodiment.

FIGS. 30A and 30B are sectional views along the X direction sequentially showing a part of the procedure of the method for manufacturing a semiconductor storage device according to another modification example of the embodiment.

FIGS. 31A and 31B are sectional views along the X direction sequentially showing a part of the procedure of the method for manufacturing a semiconductor storage device according to another modification example of the embodiment.

FIGS. 32A and 32B are sectional views along the X direction sequentially showing a part of the procedure of the method for manufacturing a semiconductor storage device according to another modification example of the embodiment.

FIGS. 33A and 33B are sectional views along the X direction sequentially showing a part of the procedure of the method for manufacturing a semiconductor storage device according to another modification example of the embodiment.

FIGS. 34A and 34B are sectional views along the X direction showing a part of the procedure of the method for manufacturing a semiconductor storage device according to another modification example of the embodiment.

FIGS. 35A and 35B are sectional views along the X direction sequentially showing a part of the procedure of the method for manufacturing a semiconductor storage device according to another modification example of the embodiment.

FIGS. 36A and 36B are sectional views along the X direction sequentially showing a part of the procedure of the method for manufacturing a semiconductor storage device according to another modification example of the embodiment.

FIG. 37 is a sectional view showing an example of the dimensions of each portion of a contact connected to a predetermined word line in a semiconductor storage device according to another modification example of the embodiment.

FIGS. 38A and 38B are sectional views along the X direction showing a part of the procedure of the method for manufacturing a semiconductor storage device according to another modification example of the embodiment.

### DETAILED DESCRIPTION

Embodiments provide a semiconductor storage device and a method for manufacturing a semiconductor storage device, which can prevent a short circuit between a plurality of conductive layers in a stacked body.

In general, according to one embodiment, a semiconductor storage device comprising a first stacked body in which a plurality of first conductive layers and a plurality of first insulating layers are alternately stacked in a stacking direction, a second stacked body that is disposed above the first stacked body and in which a plurality of second conductive layers and a plurality of second insulating layers are alternately stacked in the stacking direction, a first pillar that extends in the first and second stacked bodies in the stacking direction and has a semiconductor layer and a memory layer that covers a side wall of the semiconductor layer, and a first contact that extends in the first and second stacked bodies in the stacking direction and is connected to one first conductive layer of the plurality of first conductive layers. The first contact has a first portion that extends in the first stacked body and is connected at a lower end portion thereof to the one first conductive layer, a second portion that extends in the second stacked body and is connected to an upper end portion of the first portion, the second portion having a cross-sectional area at a lower end portion thereof as viewed from the stacking direction that is smaller than a cross-sectional area at the upper end portion of the first portion as viewed from the stacking direction, and a third conductive layer that continuously extends in the first and second portions in the stacking direction.

Hereinafter, embodiments of the present disclosure will be described in detail with reference to the drawings. Further, the scope of the present disclosure is not limited to the following embodiments. The elements in the following embodiments include those that can be easily modified by those skilled in the art or those that are substantially the same.

### Configuration Example of Semiconductor Storage Device

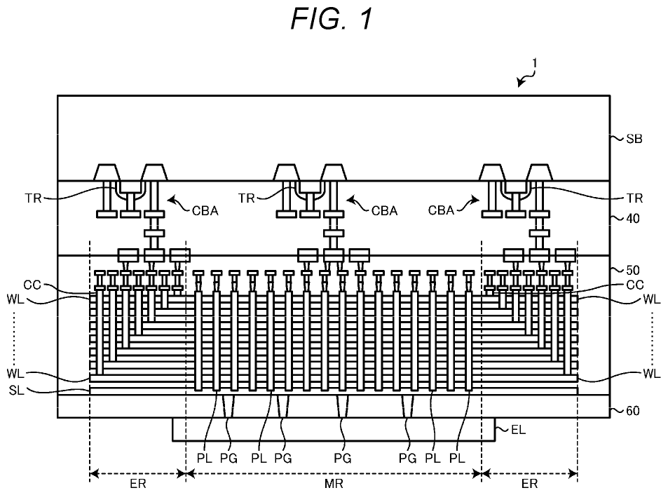

FIG. 1 is a sectional view showing a schematic configuration example of a semiconductor storage device 1 according to an embodiment. In FIG. 1, hatching is omitted in consideration of visibility of the drawing.

As shown in FIG. 1, the semiconductor storage device 1 includes an electrode film EL, a source line SL, and a plurality of word lines WL in order from the lower side of the drawing. In addition, the semiconductor storage device 1 includes a peripheral circuit CBA provided on the semiconductor substrate SB that is above the plurality of word lines WL.

The source line SL is disposed on the electrode film EL via the insulating layer 60. A plurality of the plugs PG are disposed in the insulating layer 60, and the source line SL and the electrode film EL are electrically connected through the plugs PG. Accordingly, the source voltage can be applied to the source line SL from the outside of the semiconductor storage device 1 via the electrode film EL and the plug PG. The electrode film EL and the plug PG may be integrally formed.

A plurality of word lines WL are stacked above the source line SL. A memory region MR is provided at a central portion of the plurality of word lines WL, and contact regions ER are provided at both end portions of the plurality of word lines WL.

Pillars PL penetrating the word line WL in the stacking direction are disposed in the memory region MR. Intersection portions between the pillar PL and the word line WL function as a plurality of memory cells. Accordingly, the semiconductor storage device 1 is configured as, for example, a three-dimensional nonvolatile memory in which memory cells are disposed three-dimensionally in the memory region MR.

A plurality of contacts CC respectively connected to the plurality of word lines WL are disposed in the contact region ER. In the present specification, in the extension direction of the contact CC, the connection end side of the contact CC with the word line WL is the lower side of the semiconductor storage device 1.

Various voltages are applied to the memory cell from the contact CC through the word line WL at the same height position as the memory cell. The various voltages include, for example, write voltage and read voltage. As described above, electrical connections to the word lines WL that are stacked in multiple layers are individually made through these contacts CC.

The plurality of word lines WL, the plurality of pillars PL, and the plurality of contacts CC are covered with the insulating layer 50. The insulating layer 50 also extends around the plurality of word lines WL.

The semiconductor substrate SB above the insulating layer 50 is, for example, a silicon substrate. A peripheral circuit CBA including a transistor TR, wiring, and the like is disposed on a surface of the semiconductor substrate SB. Various voltages applied from the contacts CC to the memory cell are controlled by the peripheral circuit CBA electrically connected to the contacts CC. In this way, the peripheral circuit CBA controls the electrical operation on the memory cell.

The peripheral circuit CBA is covered with the insulating layer 40, and the insulating layer 40 and the insulating layer 50, which covers the plurality of word lines WL, are bonded to each other, whereby the semiconductor storage device 1 including the configuration of the plurality of word lines WL, the plurality of pillars PL, the plurality of contacts CC, and the like and the peripheral circuit CBA is formed.

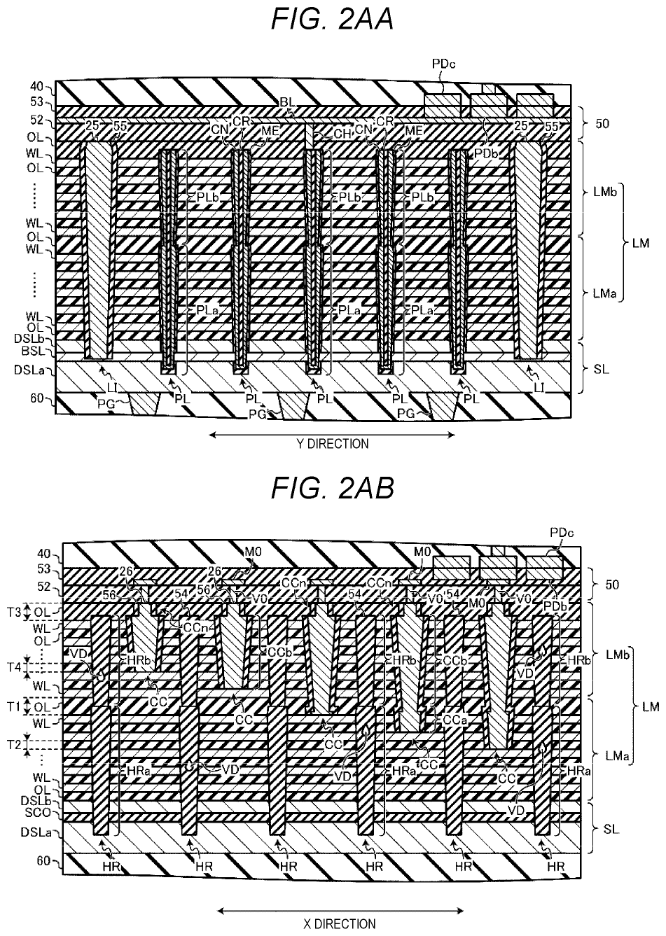

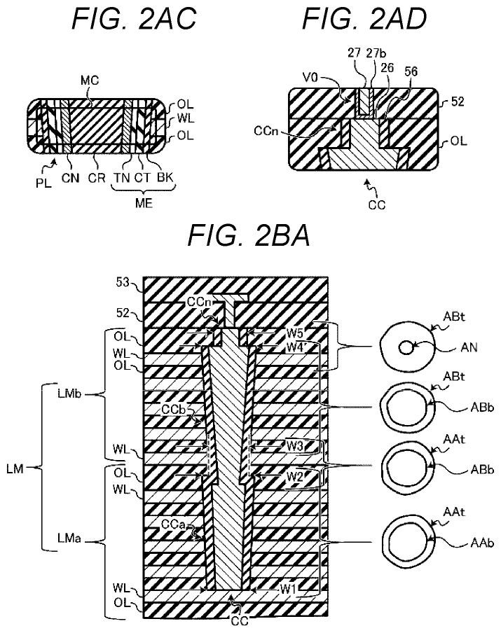

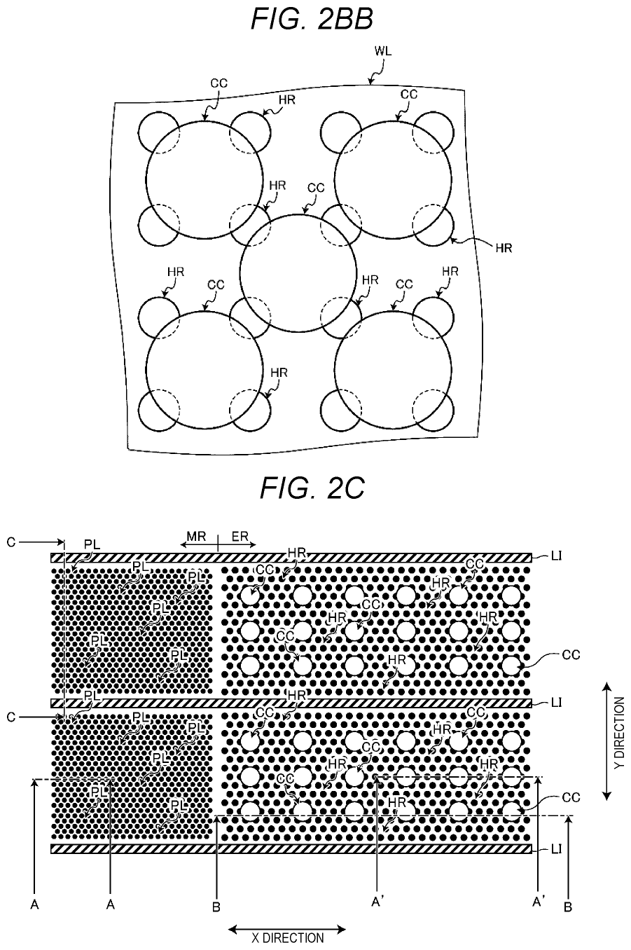

Next, a detailed configuration example of the semiconductor storage device 1 will be described with reference to FIGS. 2AA to 2BB. FIGS. 2AA to 2BB are views showing an example of a configuration of a semiconductor storage device 1 according to the embodiment.

More specifically, FIG. 2AA is a sectional view along the Y direction showing an example of the configuration of the memory region MR. FIG. 2AB is a sectional view along the X direction showing an example of the configuration of the contact region ER. In FIG. 2AA and FIG. 2AB, the structure below the insulating layer 60 and above the insulating layer 40 is not shown.

FIG. 2AC is an enlarged sectional view of the pillar PL disposed in the memory region MR. FIG. 2AD is an enlarged sectional view showing the upper end portion of the contact CC disposed in the contact region ER connected to the plug V0.

FIG. 2BA is a sectional view showing an example of the dimensions of each portion of the contact CC connected to the predetermined word line WL. FIG. 2BB is a sectional view in the XY direction at the height position of a certain word line WL, showing an example of the positional relationship between the contact CC and the columnar portion HR.

FIGS. 2AA to 2BB are views schematically showing the configuration of the semiconductor storage device 1. Therefore, the number and the positional relationship of each configuration in the sectional view in the X direction of FIG. 2AB and the XY sectional view of FIG. 2BB do not necessarily coincide across the figures.

In addition, in the present specification, both the X direction and the Y direction are directions along the direction of the plane of the word line WL, and the X direction and the Y direction are orthogonal to each other. In addition, a direction in which electricity flows in the word line WL, that is, a direction between the connection ends of the word line WL and the contact CC may be referred to as a first direction, and the first direction is a direction along the X direction. In addition, a direction intersecting the first direction may be referred to as a second direction, and the second direction is a direction along the Y direction. Meanwhile, since the semiconductor storage device 1 may include a manufacturing error, the first direction and the second direction are not necessarily orthogonal to each other.

As shown in FIG. 2AA and FIG. 2AB, the source line SL has a multilayer structure in which, for example, a lower source line DSLa, an intermediate source line BSL or an intermediate insulating layer SCO, and an upper source line DSLb are stacked in this order on the insulating layer 60. The intermediate source line BSL is disposed below the memory region MR, and the intermediate insulating layer SCO is disposed below the contact region ER.

The lower source line DSLa, the intermediate source line BSL, and the upper source line DSLb are, for example, a polysilicon layer. Among the above, at least the intermediate source line BSL may be a conductive polysilicon layer or the like in which impurities are diffused. The intermediate insulating layer SCO is, for example, a silicon oxide layer.

The stacked body LM is disposed on the source line SL. The stacked body LM includes stacked bodies LMa and LMb in which a plurality of word lines WL and a plurality of insulating layers OL are alternately stacked one by one. The stacked body LMa is disposed above the source line SL, and the stacked body LMb is disposed on the stacked body LMa.

The word line WL is, for example, a tungsten layer, a molybdenum layer. The insulating layer OL is, for example, a silicon oxide layer. The number of layers of the word lines WL stacked in the stacked body LM is predetermined.

The layer thicknesses T1 and T3 of the uppermost insulating layers OL of the stacked bodies LMa and LMb are, for example, thicker than the layer thicknesses T2 and T4 of the other insulating layers OL in the stacked bodies LMa and LMb, respectively. The layer thicknesses T1 and T3 of the uppermost insulating layers OL of the stacked bodies LMa and LMb may be equal to each other, and the layer thicknesses T2 and T4 of the other insulating layers OL in the stacked bodies LMa and LMb may be equal to each other.

The uppermost insulating layer OL of the stacked body LMa is connected to the word line WL of the lowermost layer of the stacked body LMb, and the insulating layers 52 and 53 are disposed in this order on the uppermost insulating layer OL of the stacked body LMb. The insulating layers 52 and 53 form a part of the insulating layer 50 described above, and the upper surface of the insulating layer 53 is in contact with the lower surface of the insulating layer 40 on the peripheral circuit CBA side.

As shown in FIG. 2AA, the stacked body LM is divided in the Y direction by a plurality of plate-shaped contacts LI.

That is, the plate-shaped contacts LI are arranged in the Y direction, and extends in the direction along the stacking direction of the stacked body LM and the X direction. As described above, the plate-shaped contact LI continuously extends in the stacked body LM from one end portion to the other end portion of the stacked body LM in the X direction. In addition, the plate-shaped contact LI penetrates the stacked body LM and the upper source line DSLb, and reaches the intermediate source line BSL in the memory region MR and the intermediate insulating layer SCO in the contact region ER.

In addition, the plate-shaped contact LI has, for example, a tapered shape in which the width in the Y direction is reduced from the upper end portion toward the lower end portion. Alternatively, the plate-shaped contact LI has, for example, a bowing shape in which the width in the Y direction is maximum at a predetermined position between the upper end portion and the lower end portion.

In addition, each of the plate-shaped contacts LI includes the insulating layer 55 and the conductive layer 25. The insulating layer 55 is, for example, a silicon oxide layer. The conductive layer 25 is, for example, a tungsten layer or a conductive polysilicon layer.

The insulating layer 55 covers the side wall of the plate-shaped contact LI facing the Y direction. The conductive layer 25 fills the interior side of the insulating layer 55 and is electrically connected to the source line SL including the intermediate source line BSL. In addition, the conductive layer 25 is connected to the upper layer wiring in a cross section different from that in FIG. 2AA. With such a configuration, the plate-shaped contact LI functions as a source line contact.

Meanwhile, instead of the plate-shaped contact LI, a plate-shaped member filled with an insulating layer may penetrate the stacked body LM and extend in the direction along the X direction, so that the stacked body LM may be divided in the Y direction. In this case, such a plate-shaped member does not have a function as a source line contact.

As shown in FIG. 2AA, in the memory region MR, a plurality of pillars PL are disposed, the plurality of pillars PL penetrate the stacked body LM, the upper source line DSLb, and the intermediate source line BSL and reach the lower source line DSLa.

The plurality of pillars PL are arranged in a staggered shape, for example, as viewed from the stacking direction of the stacked body LM. Each of the pillars PL has a shape such as a circular shape, an elliptical shape, or an oval shape as a cross-sectional shape in a direction along the stacking direction of the stacked body LM, that is, a direction along the XY plane.

In addition, the pillar PL has a pillar PLa, which penetrates the stacked body LMa from the uppermost insulating layer OL of the stacked body LMa and reaches the source line SL, and a pillar PLb, which penetrates the stacked body LMb from uppermost the insulating layer OL of the stacked body LMb, reaches the uppermost insulating layer OL of the stacked body LMa, and is connected to the upper end portion of the corresponding pillar PLa.

Both of the pillars PLa and PLb have a tapered shape in which the diameter and the cross-sectional area in the XY plane are reduced from the upper layer side toward the lower layer side. Alternatively, the pillars PLa and PLb each have, for example, a bowing shape in which the diameter and the cross-sectional area are maximized at a predetermined position between the upper layer side and the lower layer side.

Each of the plurality of pillars PL has a memory layer ME, a channel layer CN, and a core layer CR. The memory layer ME extends in the stacked body LM in the stacking direction. The channel layer CN penetrates the stacked body LM and is connected to the intermediate source line BSL. The core layer CR is a core material of the pillar PL.

The memory layer ME is disposed on the side surface of the pillar PL excluding the height position of the intermediate source line BSL. In addition, the memory layer ME is also disposed on the bottom surface of the pillar PL located in the lower source line DSLa.

The channel layer CN reaches the lower source line DSLa by penetrating the stacked body LM, the upper source line DSLb, and the intermediate source line BSL inside the memory layer ME. The core layer CR further fills the inside of the channel layer CN.

Meanwhile, a part of the channel layer CN is in contact with the intermediate source line BSL on the side surface, and thus is electrically connected to the source line SL including the intermediate source line BSL. In addition, the upper end portion of the channel layer CN is connected to the bit line BL extending in the insulating layer 53 in the direction along the Y direction via the plug CH disposed in the insulating layer 52.

As shown in FIG. 2AC, the memory layer ME has a multilayer structure in which the block insulating layer BK, the charge storage layer CT, and the tunnel insulating layer TN are stacked in this order from the outer peripheral side of the pillar PL.

The block insulating layer BK and the tunnel insulating layer TN of the memory layer ME, and the core layer CR are, for example, a silicon oxide layer. The charge storage layer CT of the memory layer ME is, for example, a silicon nitride layer. The channel layer CN is, for example, a semiconductor layer such as a polysilicon layer or an amorphous silicon layer.

With the above configuration, the portions facing the individual word lines WL on the side surface of the pillar PL function as the memory cells MC, respectively. A predetermined voltage is applied to the word line WL to write and read data to and from the memory cell MC.

The data from the memory cell MC is read out to the bit line BL connected to the pillar PL. The bit line BL is connected to the electrode pad PDb disposed on the surface of the insulating layer 53. The electrode pad PDb is connected to the electrode pad PDc. The electrode pad PDc is disposed on the surface of the insulating layer 40 and is electrically connected to the peripheral circuit CBA. Accordingly, the data of the memory cell MC read out to the bit line BL is processed by the peripheral circuit CBA.

As shown in FIG. 2AB, a plurality of contacts CC and a plurality of columnar portions HR are disposed in the contact region ER.

Some of the plurality of contacts CC extend in the stacked bodies LMa and LMb in the stacking direction of the stacked body LM and are connected to the plurality of word lines WL belonging to the stacked body LMa, respectively. Some others of the plurality of contacts CC extend in the stacked body LMb in the stacking direction of the stacked body LM and are connected to the plurality of word lines WL belonging to the stacked body LMb, respectively.

The contact CC connected to the word line WL of the stacked body LMa has a contact portion CCa and a contact portion CCb. The contact portion CCa extends in the stacked body LMa in the stacking direction, and the contact portion CCb extends in the stacked body LMb in the stacking direction. The contact CC connected to the word line WL of the stacked body LMb has a contact portion CCb and does not have a contact portion CCa.

The contact portion CCa of the contact CC connected to the word line WL of the stacked body LMa, is connected at the lower end thereof to the word line WL. The contact portion CCb of the contact CC connected to the word line WL of the stacked body LMa, is connected at the lower end thereof to the upper end of the corresponding contact portion CCa by penetrating the stacked body LMb. The contact portion CCb of the contact CC connected to the word line WL of the stacked body LMb, is connected at the lower end thereof to the word line WL.

The upper end portion of the contact portion CCa is disposed in, for example, the uppermost insulating layer OL of the stacked body LMa. In addition, the upper end portion of the contact portion CCb is disposed in, for example, the uppermost insulating layer OL of the stacked body LMb.

Both of the contact portions CCa and CCb have, for example, a tapered shape in which the diameter and the cross-sectional area in the XY plane are reduced from the upper end portion toward the lower end portion. That is, in the example of FIG. 2BA, the diameter W1 of the lower end portion of the contact portion CCa is smaller than the diameter W2 of the upper end portion, and the diameter W3 of the lower end portion of the contact portion CCb is smaller than the diameter W4 of the upper end portion. In addition, the cross-sectional area AAb of the lower end portion of the contact portion CCa in the XY plane is smaller than the cross-sectional area AAt of the upper end portion of the contact portion CCa in the XY plane, and the cross-sectional area ABb of the lower end portion of the contact portion CCb in the XY plane is smaller than the cross-sectional area ABt of the upper end portion of the contact portion CCb in the XY plane.

In addition, the contact portion CCa has an upper end portion having a larger diameter and a larger cross-sectional area in the XY plane than the lower end portion of the contact portion CCb. That is, in the example of FIG. 2BA, the diameter W2 of the upper end portion of the contact portion CCa is larger than the diameter W3 of the lower end portion of the contact portion CCb. In addition, the cross-sectional area AAt of the upper end portion of the contact portion CCa in the XY plane is larger than the cross-sectional area ABb of the lower end portion of the contact portion CCb in the XY plane.

Alternatively, the contact portion CCa and CCb each have, for example, a bowing shape in which the diameter and the cross-sectional area are maximized at a predetermined position between the upper end portion and the lower end portion. In this case, the diameter W2, which is the maximum diameter of the contact portion CCa, is located between the upper end portion and the lower end portion of the contact portion CCa. In addition, the diameter W4, which is the maximum diameter of the contact portion CCb, is located between the upper end portion and the lower end portion of the contact portion CCb. Even in this case, the contact portion CCa has an upper end portion having a larger diameter and a larger cross-sectional area in the XY plane than the lower end portion of the contact portion CCb.

In the contact CC connected to the word line WL of the stacked body LMa, the contact portions CCa and CCb are connected in the uppermost insulating layer OL of the stacked body LMa. In addition, the diameter and the cross-sectional area in the XY plane of the contact CC are discontinuously changed in the insulating layer OL.

That is, in the contact CC connected to the word line WL of the stacked body LMa, in the uppermost insulating layer OL of the stacked body LMa, the diameter is once narrowed at the lower end portion of the contact portion CCb and is discontinuously increased at the upper end portion of the contact portion CCa. Accordingly, the contact CC connected to the word line WL of the stacked body LMa has a step at the connection portion between the contact portion CCb and the contact portion CCa.

Meanwhile, although the diameter of the contact CC is narrowed at the connection portion between the contact portions CCa and CCb, the contact portion CCa may not have a tapered shape or a bowing shape, and may have, for example, a vertical shape. The vertical shape is, for example, a shape in which the side wall of the contact portion CCa extends substantially vertically, and the diameters and the cross-sectional areas in the XY plane at the upper and lower ends of the contact portion CCa are substantially equal to each other. Even in this case, the diameter of the contact portion CCb having a tapered shape or a bowing shape is narrowed at the lower end portion, and the diameter of the contact CC is discontinuously changed at the connection portion between the contact portions CCa and CCb.

In addition, each of the plurality of contacts CC extends in the uppermost insulating layer OL of the stacked body LMb, and has a neck portion CCn connected to the upper end portion of the contact portion CCb disposed in the insulating layer OL.

The neck portion CCn has a substantially vertical shape and extends in the insulating layer OL, and has a diameter and a cross-sectional area that are smaller than the diameter and the cross-sectional area at the upper end portion of the contact portion CCb, respectively.

That is, in the example of FIG. 2BA, the diameter W5 of the neck portion CCn is smaller than the diameter W4 of the upper end portion of the contact portion CCb. In addition, the cross-sectional area AN of the neck portion CCn in the XY plane is smaller than the cross-sectional area ABt of the upper end portion of the contact portion CCb in the XY plane.

In the above description, a case where the cross-sectional shape of each portion of the contact CC in the XY plane is, for example, a circular shape is assumed. That is, in the above example, the size relationship between the diameter and the cross-sectional area in the XY plane of each portion of the contact CC substantially coincides. When the cross section of each portion of the contact CC in the XY plane is, for example, a shape other than a circular shape such as an elliptical shape, an oval shape, or a polygonal shape, the diameters W1 to W5 of each portion of the contact CC described above may be rephrased as widths representing that portion of the contact CC. The width representing each portion of the contact CC is a width of a portion where the size relationship coincides with the cross-sectional area of that portion of the contact CC in the XY plane, such as the maximum width, the minimum width, the average width of the maximum width and the minimum width, or the like of that portion. The same applies to the following description when reference is made to the “diameter” of each portion of the contact CC. In such cases, the definition described above is applied.

The contact CC has an insulating layer 56 that covers the outer periphery of the contact CC, and a conductive layer 26 such as a tungsten layer or a copper layer that fills the interior of the insulating layer 56.

The conductive layer 26 continuously extends in the contact CC from the upper end portion of the contact CC, that is, the upper end portion of the neck portion CCn disposed in the uppermost insulating layer OL of the stacked body LMb to the lower end portion of the contact CC, that is, the connection end to the word line WL to be connected in the stacked body LMa or the stacked body LMb.

The diameter and the cross-sectional area in the XY plane of the conductive layer 26 vary depending on its height position in the stacked body LM, in substantially similar manner as the diameter and the cross-sectional area of the contact CC.

That is, the diameter of the conductive layer 26 is relatively small in the neck portion CCn, is increased once at the upper end portion of the contact portion CCb, and is reduced toward the lower end portion of the contact portion CCb. In addition, when the contact CC has the contact portion CCa in addition to the neck portion CCn and the contact portion CCb, the diameter of the conductive layer 26 is further increased again at the upper end portion of the contact portion CCa and is reduced again toward the lower end portion of the contact portion CCa.

In addition, the insulating layer 56 continuously covers the conductive layer 26 at least in the contact portions CCa and CCb. That is, the insulating layer 56 also continuously covers the step of the conductive layer 26 at the connection portion between the contact portions CCa and CCb, and thus the outer shape of the insulating layer 56 substantially coincides with the outer shape of the contact CC.

In addition, in FIG. 2AB, the insulating layer 56 that covers the conductive layer 26 in the neck portion CCn of the contact CC and the insulating layer 56 that covers the contact portions CCa and CCb are not continuous. However, the present disclosure is not limited thereto, the insulating layer 56 that covers the conductive layer 26 in the neck portion CCn of the contact CC and the insulating layer 56 that covers the contact portions CCa and CCb may be continuous. Alternatively, since the conductive layer 26 in the neck portion CCn of the contact CC is disposed in the insulating layer OL, the insulating layer 56 does not need to cover the conductive layer 26 in the neck portion CCn.

The conductive layer 26 of the contact CC is connected to the upper layer wiring M0 disposed in the insulating layer 53 via the plug V0 disposed in the insulating layer 52. The upper layer wiring M0 is electrically connected to the peripheral circuit CBA (refer to FIG. 1) described above via the electrode pad PDb on the surface of the insulating layer 53, the electrode pad PDc on the surface of the insulating layer 40, and the like.

As shown in FIG. 2AD, the plug V0 includes the conductive layer 27 penetrating the insulating layer 52, and the barrier metal layer 27b covering the side wall and the lower end portion of the conductive layer 27. The barrier metal layer 27b is a titanium layer, a tantalum layer, a titanium nitride layer, a tantalum nitride layer, or the like. The barrier metal layer 27b prevents the conductive layer 27 of the plug V0 from diffusing into the insulating layer 52 and affecting other configurations.

With such a configuration, the word line WL of each layer can be electrically led out. That is, with the above configuration, the predetermined voltage can be applied to the memory cell MC from the peripheral circuit CBA through the upper layer wiring M0, the contact CC, and the word line WL, and the memory cell MC can be operated as a storage element.

As described above, the columnar portions HR reaching the lower source line DSLa by penetrating the stacked body LM, the upper source line DSLb, and the intermediate insulating layer SCO are disposed in the contact region ER in which the plurality of contacts CC are disposed. The plurality of columnar portions HR are disposed in a grid shape or a staggered shape, for example, as viewed from the stacking direction of the stacked body LM. Each of the columnar portions HR has a shape such as a circular shape, an elliptical shape, or an oval shape as a cross-sectional shape in a direction along the XY plane.

In the example of FIG. 2AB, the plurality of columnar portions HR are disposed between the plurality of contacts CC, respectively. Meanwhile, as shown in FIG. 2BB, the plurality of columnar portions HR are disposed, for example, at a pitch smaller than the diameter of the contacts CC, respectively, and the interference with the plate-shaped contact LI and the contact CC is allowed. That is, some of the plurality of columnar portions HR may be disposed at a position at least partially overlapping with the adjacent contact CC, and the portion overlapping with the contact CC may be eroded by the contact CC to be in a missing state.

In addition, in the example of FIG. 2BB, the plurality of columnar portions HR may have a grid-shaped disposition as viewed from the stacking direction of the stacked body LM. Meanwhile, as described above, the plurality of columnar portions HR may have, for example, a staggered-shaped disposition.

In addition, each of the columnar portions HR has a columnar portion HRa and a columnar portion HRb. The columnar portion HRa reaches the source line SL from the uppermost insulating layer OL of the stacked body LMa by penetrating the stacked body LMa. The columnar portion HRb reaches the uppermost insulating layer OL of the stacked body LMa by penetrating the stacked body LMb from the uppermost insulating layer OL of the stacked body LMb, and is connected to the upper end portion of the corresponding columnar portion HRa.

Both of the columnar portions HRa and HRb have, for example, a tapered shape in which the diameter and the cross-sectional area in the XY plane are reduced from the upper end portion toward the lower end portion. Alternatively, the columnar portions HRa and HRb each have, for example, a bowing shape in which the diameter and the cross-sectional area are maximized at a predetermined position between the upper end portion and the lower end portion.

As will be described later, the columnar portions HR have a role of supporting these configurations when the stacked body LM is formed from the stacked body in which the sacrificial layer and the insulating layer are stacked. That is, the columnar portion HR is a dummy pillar that does not contribute to the function of the memory cell MC of the semiconductor storage device 1.

Therefore, each of the columnar portions HRa and HRb is formed of the single insulating layer 54 such as the silicon oxide layer, and the columnar portion HR may not have an electrical influence on other configurations. As a result, as described above, the plurality of columnar portions HR may be disposed at a position where at least a part overlaps the adjacent plate-shaped contact LI and the contact CC, and as described above, the interference in the physical disposition with the adjacent plate-shaped contact LI and the contact CC is allowed.

By configuring the columnar portion HR in this way, the columnar portion HR can be disposed at a desired pitch without considering the contact with the plate-shaped contact LI and the contact CC. The columnar portion HR may be formed of different insulating layers, and not just the insulating layer 54, as long as the columnar portion HR does not have an electrical influence on other configurations.

In the insulating layer 54, a void VD, which is an unfilled portion generated when the insulating layer 54 is formed, may be generated.

In addition, at the same height position of the stacked body LM, the cross-sectional area of the columnar portion HR in the direction along the XY plane may be larger than, for example, the cross-sectional area of the pillar PL in the direction along the XY plane. In addition, the pitch between the plurality of columnar portions HR may be larger than the pitch between the plurality of pillars PL, for example. In the XY plane, the density of the columnar portions HR per unit area of the word line WL in the stacked body LM may be less than the density of the pillars PL per unit area of the word line WL.

In this way, for example, by forming the cross-sectional area of the pillar PL to be smaller than that of the columnar portion HR and arranging the pillar PL with a narrower pitch, a large number of memory cells MC can be formed in the stacked body LM having a predetermined size at a high density, and the storage capacity of the semiconductor storage device 1 can be increased. Meanwhile, since the columnar portion HR is used exclusively to support the stacked body LM, for example, the manufacturing load of the semiconductor storage device 1 can be reduced by not forming the columnar portion HR to have a small cross-sectional area and a narrow pitch like the pillar PL.

An XY sectional view of the semiconductor storage device 1 of the embodiment configured as described above is shown in FIG. 2C. FIG. 2C is an XY sectional view showing an example of a configuration of a semiconductor storage device 1 according to the embodiment. FIG. 2C is an XY sectional view at a height position of a certain word line WL, and shows a part of the memory region MR and a part of the contact region ER of the semiconductor storage device 1.

FIG. 2C and each of FIGS. 2AA to 2BB described above schematically show the configuration of the semiconductor storage device 1. Therefore, for example, the number, the disposition, and the like of each configuration in the sectional view in the X direction or the Y direction of FIGS. 2AA and 2AB and the XY sectional view of FIG. 2C do not necessarily coincide across the figures. In addition, for example, in FIG. 2C, the columnar portion HR has a staggered-shaped disposition, and thus, the six columnar portions HR interfere with one contact CC. Meanwhile, when columnar portion HR has the grid-shape disposition shown in FIG. 2BB, the number of columnar portions HR interfering with one contact CC is, for example, four.

As shown in FIG. 2C, a plurality of pillars PL are disposed in the memory region MR, for example, in a staggered shape, as described above. In addition, in the example of FIG. 2C, the plurality of columnar portions HR are also disposed in a staggered shape in the contact region ER. As described herein, the columnar portion HR has, for example, a size and a pitch larger than the size and the pitch of the pillar PL.

Lines A-A to C-C shown in FIG. 2C depict cross sections that show a method for manufacturing the semiconductor storage device 1 to be described later. The number, the disposition, and the like of each configuration in each sectional view showing the method for manufacturing the semiconductor storage device 1 and the XY sectional view of FIG. 2C may not necessarily coincide across the sectional views.

### Method for Manufacturing Semiconductor Storage Device

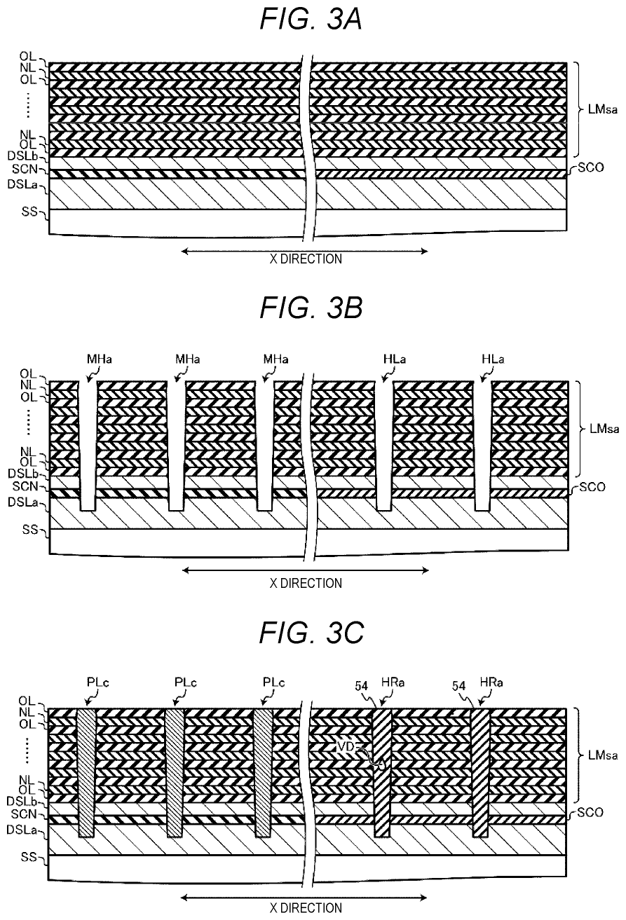

Next, a method for manufacturing a semiconductor storage device 1 according to the embodiment will be described with reference to FIGS. 3A to 24B. FIGS. 3A to 24B are views sequentially showing a part of a procedure of a method for manufacturing a semiconductor storage device 1 according to the embodiment.

First, a state in which a configuration that is to be a part of the pillar PL and the columnar portion HR is formed, is shown in FIGS. 3A to 3C. FIGS. 3A to 3C show a cross section of the semiconductor storage device 1 under manufacturing along the X direction. That is, the cross section showing the configuration that is to be a part of the pillar PL in FIGS. 3A to 3C corresponds to the cross-sectional portion taken along line A-A in FIG. 2C described above. In addition, the cross section showing the configuration that is to be a part of the columnar portion HR in FIGS. 3A to 3C corresponds to the cross-sectional portion taken along line A′-A′ in FIG. 2C described above.

As shown in FIG. 3A, the lower source line DSLa, the intermediate sacrificial layer SCN or the intermediate insulating layer SCO, and the upper source line DSLb are formed in this order above the supporting substrate SS.

The supporting substrate SS is, for example, a semiconductor substrate such as a silicon substrate, an insulating substrate such as a ceramic substrate or a quartz substrate, or a conductive substrate such as a sapphire substrate.

The intermediate sacrificial layer SCN is a layer which is later replaced with a polysilicon layer or the like to be the intermediate source line BSL, and is disposed in a region that is to be the memory region MR. The intermediate insulating layer SCO is, for example, a silicon oxide layer or the like, and is disposed in a region that is to be the contact region ER.

A stacked body LMsa in which insulating layers NL and insulating layers OL are alternately stacked one by one is formed on the upper source line DSLb. The insulating layer NL is, for example, a silicon nitride layer, and functions as a sacrificial layer to be replaced with a conductive material that is to be the word line WL. The stacked body LMsa is a portion that is to be the stacked body LMa via such a replacement processing.

At this stage, the plurality of insulating layers OL including the uppermost insulating layer OL may have approximately the same thickness.

As shown in FIG. 3B, memory holes MHa are formed in a region which is to be the memory region MR. The memory hole MHa penetrates the stacked body LMsa, the upper source line DSLb, and the intermediate sacrificial layer SCN and reaches the lower source line DSLa. In addition, a plurality of holes HLa are formed in a region that is to be the contact region ER. The plurality of holes HLa penetrate the stacked body LMsa, the upper source line DSLb, and the intermediate insulating layer SCO and reach the lower source line DSLa.

These memory holes MHa and holes HLa may be formed together, for example. Alternatively, the memory hole MHa and the hole HLa may be individually formed. When the memory hole MHa and the hole HLa are individually formed, when forming the memory hole MHa, a region that is to be the contact region ER can be protected with a resist layer or the like. In addition, when forming the hole HLa, a region that is to be the memory region MR can be protected with a resist layer or the like.

As shown in FIG. 3C, for example, the memory hole MHa is filled with a sacrificial layer of an amorphous silicon layer to form a plurality of pillars PLc. In addition, for example, the insulating layer 54 of the silicon oxide layer fills the hole HLa to form the columnar portions HRa. In this case, an unfilled portion may be formed in the insulating layer 54, and a void VD may be formed.

The pillars PLc and the columnar portions HRa are individually formed. When forming the pillars PLc, a region that is to be the contact region ER is protected with a resist layer or the like. In addition, when forming the columnar portions HRa, a region that is to be the memory region MR is protected with a resist layer or the like.

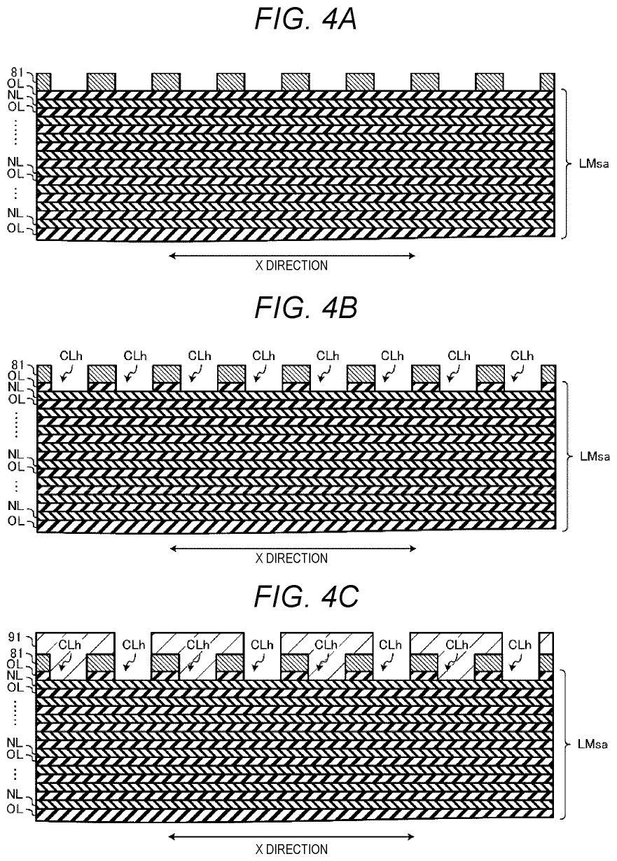

Next, the state in which the configuration that is to be a part of the contact CC is formed is shown with reference to FIGS. 4A to 7C, the contact CC being connected to any word line WL of the stacked body LMa.

FIGS. 4A to 6C show a cross-sectional portion that is a cross section of the contact region ER in the middle of manufacturing along the X direction and that corresponds to the cross section taken along line B-B of FIG. 2C described above. In FIGS. 2AA to 2AD described above, for example, the stacked bodies LMa and LMb each including the five layers of word lines WL are shown. However, in FIGS. 4A to 6C, for convenience of description, an example is shown in which the contact holes CLa to CLh respectively reaching the height position of the eight insulating layers NL are formed. As described above, even when the number of layers of the word lines WL is different, there is no difference in the formation method itself of various configurations including the contact holes CLa to CLh. In addition, in FIGS. 4A to 6C, the plurality of columnar portions HRa are not shown.

As shown in FIG. 4A, a hard mask pattern 81 having a plurality of openings is formed on the upper surface of the stacked body LMsa. The hard mask pattern 81 is an inorganic layer that is not removed by ashing using, for example, oxygen plasma. Each of the plurality of openings of the hard mask pattern 81 has, for example, a hole shape.

As shown in FIG. 4B, the upper surface of the stacked body LMsa exposed from the opening of the hard mask pattern 81 is etched to remove the uppermost insulating layer OL. As a result, a plurality of contact holes CLh that penetrate the uppermost insulating layer OL and reach the insulating layer NL immediately below the insulating layer OL are formed.

As shown in FIG. 4C, a resist pattern 91 having a plurality of openings is formed. The resist pattern 91 is an organic layer such as a resist layer that may be removed by ashing using, for example, oxygen plasma. The resist pattern 91 partially covers the upper surface of the stacked body LMsa via the hard mask pattern 81. For example, every other contact hole CLh is exposed from the opening of the resist pattern 91.

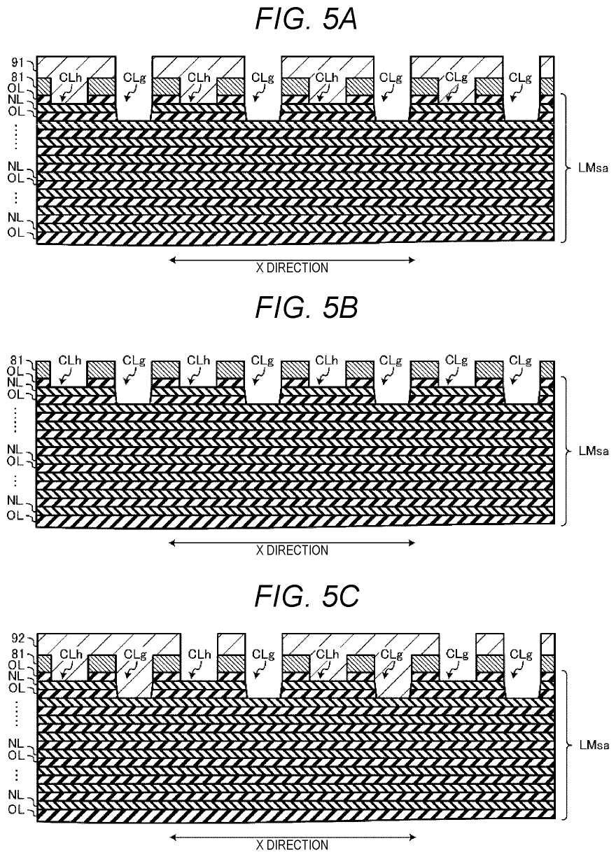

As shown in FIG. 5A, the contact hole CLh exposed from the opening of the resist pattern 91 is further etched to remove a pair of insulating layers NL and OL, for example, from the bottom surface of the contact hole CLh.

As a result, a plurality of contact holes CLg that penetrate the stacked body LMsa from the uppermost insulating layer OL to the second insulating layer OL and reach the second insulating layer NL from the uppermost insulating layer NL are formed. Every other contact hole CLg is disposed with respect to the plurality of contact holes CLh covered with the resist pattern 91.

That is, at this stage, the plurality of contact holes CLh and the plurality of contact holes CLg are alternately disposed one by one in the stacked body LMsa.

As shown in FIG. 5B, the resist pattern 91 is removed by ashing using oxygen plasma or the like.

As shown in FIG. 5C, a resist pattern 92 having a plurality of openings is formed. The resist pattern 92 partially covers the upper surface of the stacked body LMsa via the hard mask pattern 81. From the opening of the resist pattern 92, among a set including contact holes CLh and CLg adjacent to each other, for example, every other set including contact holes CLh and CLg is exposed.

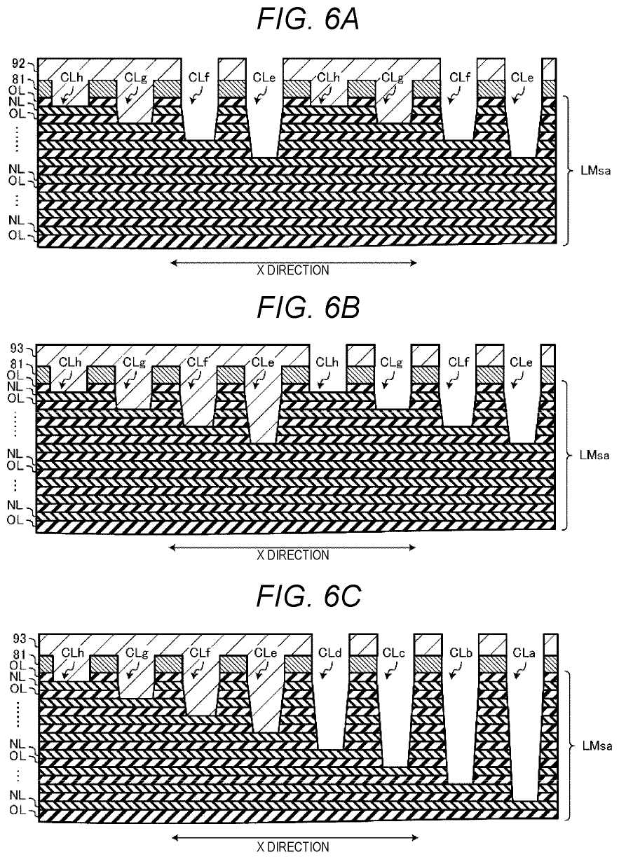

As shown in FIG. 6A, the contact holes CLh and CLg exposed from the opening of the resist pattern 92 are further etched to remove two pairs of insulating layers NL and OL, for example, from the bottom surface of the contact holes CLh and CLg, respectively.

As a result, a plurality of contact holes CLf, which penetrate the stacked body LMsa from the uppermost insulating layer OL to the third insulating layer OL and reach the third insulating layer NL from the uppermost insulating layer NL, are formed from the contact hole CLh that is the etching target.

In addition, a plurality of contact holes CLe, which penetrate the stacked body LMsa from the uppermost insulating layer OL to the fourth insulating layer OL and reach the fourth insulating layer NL from the uppermost insulating layer NL, are formed from the contact hole CLg that is the etching target.

As described above, by the processing so far, two sets of the contact holes CLh to CLe are formed in which the contact holes CLh to CLe in which the reach depths thereof in the stacked body LMsa gradually increase are arranged in this order.

Thereafter, the resist pattern 92 is removed by ashing using oxygen plasma or the like.

As shown in FIG. 6B, a resist pattern 93 having a plurality of openings is formed. The resist pattern 93 partially covers the upper surface of the stacked body LMsa via the hard mask pattern 81. From the opening of the resist pattern 93, one set including contact holes CLh to CLe is exposed out of the two sets of contact holes CLh to CLe.

As shown in FIG. 6C, the contact holes CLh to CLe exposed from the opening of the resist pattern 92 are further etched to remove four pairs of insulating layers NL and OL, for example, from the bottom surface of the contact holes CLh to CLe, respectively.

As a result, a contact hole CLd, which penetrates the stacked body LMsa from the uppermost insulating layer OL to the fifth insulating layer OL and reaches the fifth insulating layer NL from the uppermost insulating layer NL, is formed from the contact hole CLh that is the etching target.

In addition, a contact hole CLc, which penetrates the stacked body LMsa from the uppermost insulating layer OL to the sixth insulating layer OL and reaches the sixth insulating layer NL from the uppermost insulating layer NL, is formed from the contact hole CLg that is the etching target.

In addition, a contact hole CLb, which penetrates the stacked body LMsa from the uppermost insulating layer OL to the seventh insulating layer OL and reaches the seventh insulating layer NL from the uppermost insulating layer NL, is formed from the contact hole CLf that is the etching target.

In addition, a contact hole CLa, which penetrates the stacked body LMsa from the uppermost insulating layer OL to the eighth insulating layer OL and reaches the eighth insulating layer NL from the uppermost insulating layer NL, is formed from the contact hole CLe that is the etching target.

As described above, the reach depth in the stacked body LMsa gradually increases, and a plurality of contact holes CLh to CLa that respectively reach the eight insulating layers NL in the stacked body LMsa are formed. The contact holes CLh to CLa have a tapered shape or a bowing shape, and the lower end portions thereof have a diameter smaller than the upper end portions.

Thereafter, the resist pattern 93 is removed by ashing using oxygen plasma or the like. In addition, the hard mask pattern 81 is removed by etching or the like.

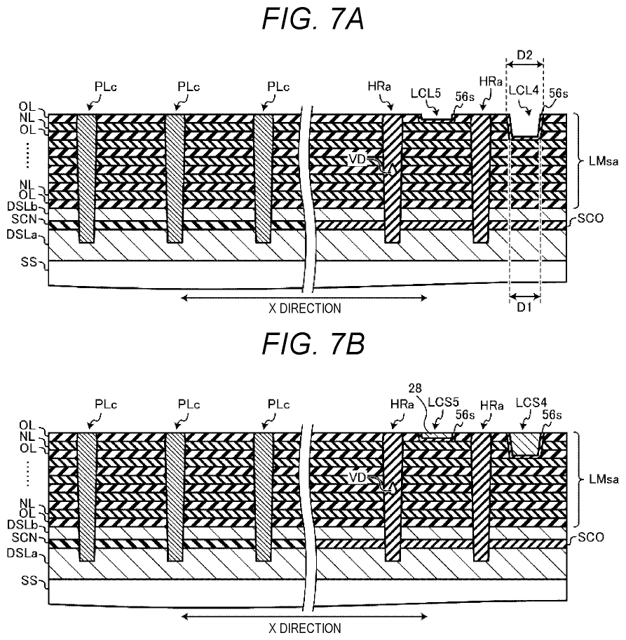

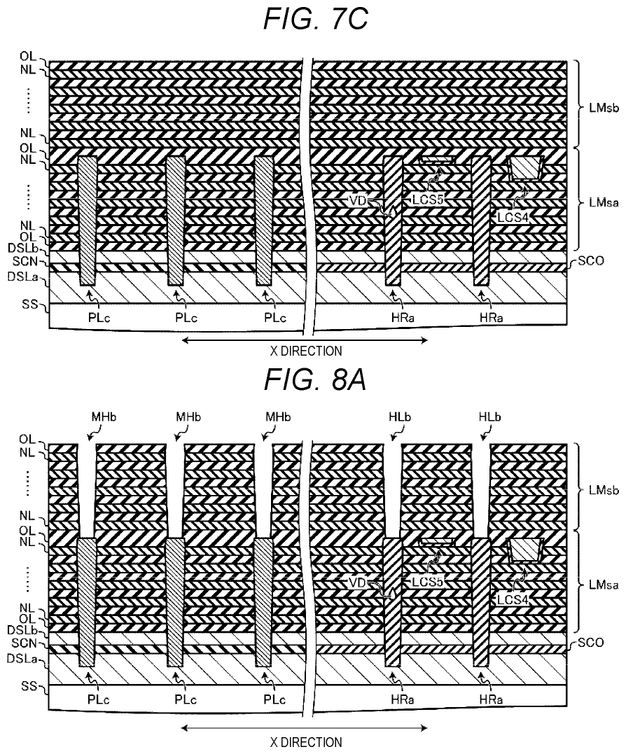

Similarly to FIGS. 3A to 3C, FIGS. 7A to 7C show a cross-sectional portion that is a cross section of the semiconductor storage device 1 under manufacturing along the X direction and that corresponds to the cross section taken along line A-A and the cross section taken along line A′-A′ of FIG. 2C described above. By the processing of FIGS. 4A to 6C described above, a plurality of contact holes are formed in a region that is to be the contact region ER.

FIG. 7A shows the contact hole LCL5 reaching the fifth insulating layer NL from the lowermost insulating layer NL of the stacked body LMsa and the contact hole LCL4 reaching the fourth insulating layer NL from the lowermost insulating layer NL, among the plurality of contact holes reaching the different insulating layers NL in the stacked body LMsa, respectively.

As described above, the plurality of contact holes including the contact holes LCL5 and LCL4 have a tapered shape in which the cross-sectional area in the XY plane at the upper end portion is maximized, or a bowing shape in which the cross-sectional area between the upper end portion and the lower end portion is maximized. That is, in the example of FIG. 7A, for example, the diameter D1 of the lower end portion of the contact hole LCL4 is smaller than the diameter D2 of the upper end portion. The diameter D2, which is the maximum diameter of the contact hole LCL4, may be located between the upper end portion and the lower end portion of the contact hole LCL4.

In addition, regardless of the example shown in FIG. 7A, the plurality of contact holes may be formed at positions overlapping with a part of the plurality of columnar portions HRa. In this case, a portion where the contact hole of the columnar portion HRa is formed may be in a missing state.

As shown in FIG. 7A, an insulating layer 56s covering the side walls and the bottom surfaces of each of the plurality of contact holes including the contact holes LCL5 and LCL4 is formed. The insulating layer 56s is, for example, a silicon oxide layer, and is formed in a subsequent processing in order to protect the side wall and the bottom surface of the contact hole. Therefore, the insulating layer 56s may be thinner than the above-described insulating layer 56 (see FIG. 2AB) in which each contact CC has the side wall.

As shown in FIG. 7B, for example, the sacrificial layer 28 of the amorphous silicon layer fills each of the plurality of contact holes including the contact holes LCL5 and LCL4 via the insulating layer 56s. Accordingly, a columnar body including the columnar bodies LCS5 and LCS4 is formed from each of the plurality of contact holes. The columnar bodies LCS5 and LCS4, and the like are temporary structures including the sacrificial layer 28 and are to be the contact portions CCa.

As shown in FIG. 7C, a silicon oxide layer or the like is further stacked on the upper surface of the stacked body LMsa. As a result, the uppermost insulating layer OL of the stacked body LMsa is thicker than the other insulating layers OL. In addition, the upper end portions of the columnar bodies LCS5 and LCS4, and the like are buried in the uppermost insulating layer OL.

In addition, a stacked body LMsb in which insulating layers NL and insulating layers OL are alternately stacked one by one is formed on the stacked body LMsa. The stacked body LMsb is a portion that is to be the stacked body LMb.

At this stage, the plurality of insulating layers OL of the stacked body LMb including the uppermost insulating layer OL may have approximately the same thickness.

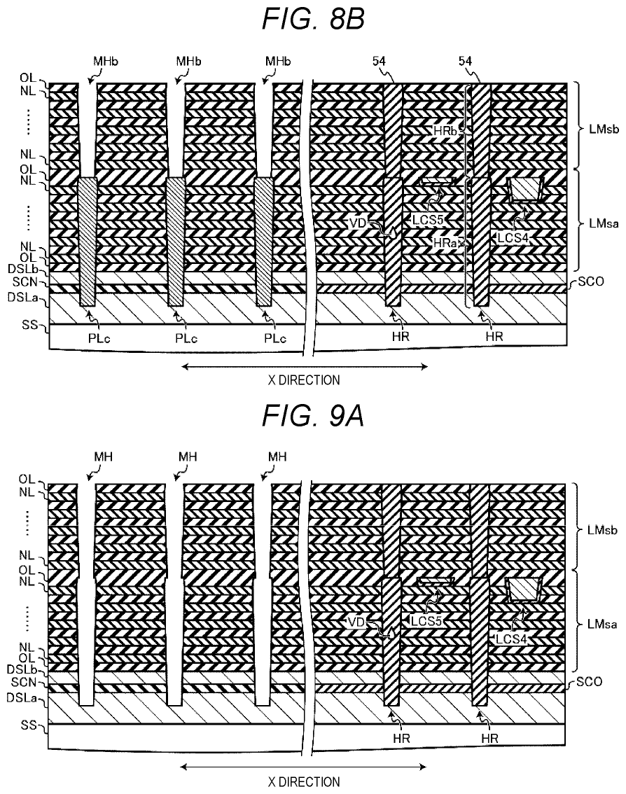

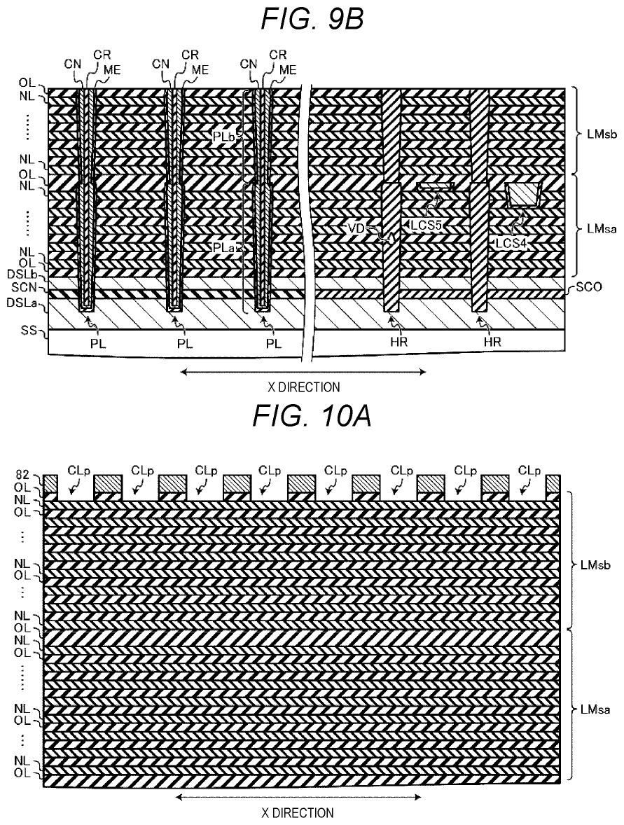

Next, a state in which the pillar PL and the columnar portion HR are formed is shown in FIGS. 8A to 9B. Similarly to FIGS. 7A to 7C, and the like, FIGS. 8A to 9B show a cross-sectional portion that is a cross section of the semiconductor storage device 1 under manufacturing along the X direction and that corresponds to the cross section taken along line A-A and the cross section taken along line A′-A′ of FIG. 2C described above.

As shown in FIG. 8A, memory holes MHb are formed in a region which is to be the memory region MR. The memory holes MHb penetrate the stacked body LMsb and reach the upper end portions of the plurality of pillars PLc disposed in the stacked body LMsa, respectively. In addition, a plurality of holes HLb are formed in a region that is to be the contact region ER. The plurality of holes HLb penetrate the stacked body LMsb and reach the upper end portions of the plurality of columnar portions HRa disposed in the stacked body LMsa, respectively.

These memory holes MHb and holes HLb may be formed together, for example. Alternatively, the memory hole MHb and the hole HLb may be individually formed while appropriately protecting a region that is to be the memory region MR and a region that is to be the contact region ER.

As shown in FIG. 8B, in a region that is to be the contact region ER, for example, the hole HLb is filled with the insulating layer 54 of the silicon oxide layer to form the columnar portions HRb. Although not shown, even in this case, an unfilled portion may be formed in the insulating layer 54, and a void VD may be formed.

Accordingly, the columnar portion HR including the columnar portions HRa and HRb is formed. When forming the columnar portion HRb, a region that is to be the memory region MR is protected with a resist layer or the like.

In a region that is to be the memory region MR, the sacrificial layer is removed from the plurality of pillars PLc respectively connected to the lower end portions of the memory holes MHb through the plurality of memory holes MHb. As a result, as shown in FIG. 9A, a plurality of memory holes MH reaching the source line SL by penetrating the stacked bodies LMsb and LMsa are formed.

As shown in FIG. 9B, a memory layer ME having a stacked structure of a block insulating layer BK, a charge storage layer CT, and a tunnel insulating layer TN (see FIG. 2AC) is formed on each of a plurality of memory holes MH in order from the outer peripheral side of the memory hole MH. In addition, the channel layer CN is formed on the side walls and the bottom surfaces of the plurality of memory holes MH. In addition, the void in the memory hole MH on the inner side of the channel layer CN is filled with the silicon oxide layer or the like to form the core layer CR.

The memory layer ME, the channel layer CN, and the core layer CR are also formed on the upper surface of the stacked body LMsb. The memory layer ME, the channel layer CN, and the core layer CR are removed from the upper surface of the stacked body LMsb by etching back or the like.

As described above, the plurality of pillars PL are formed in a region that is to be the memory region MR. Meanwhile, at this point, the memory layer ME covers the entire side walls of the plurality of pillars PL.

By the processing of FIG. 8B described above, a plurality of columnar portions HR are formed in a region that is to be the contact region ER. Therefore, the region that is to be the contact region ER is not affected by the processing shown in FIGS. 9A and 9B described above.

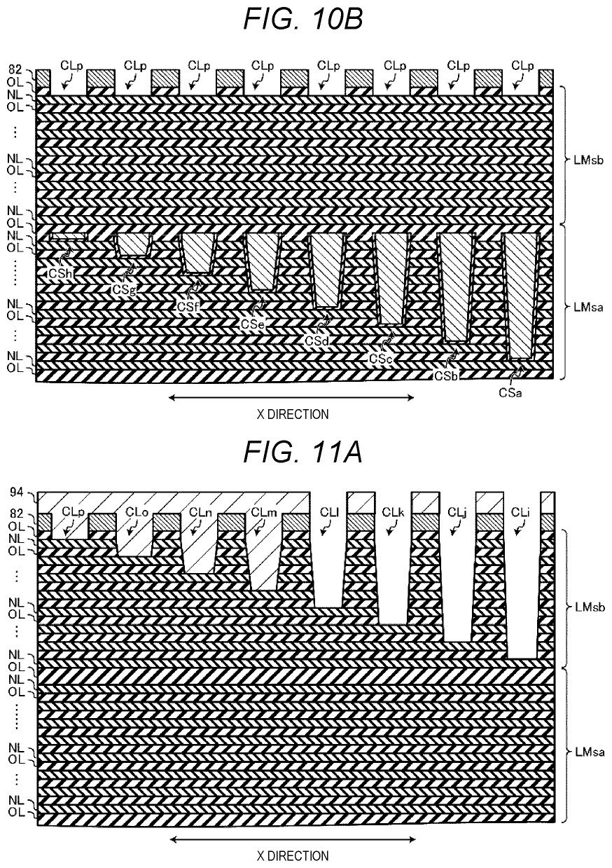

Next, the state in which the configuration that is to be a part of the contact CC is formed is shown with reference to FIGS. 10A to 15B, the contact CC being connected to one word line WL of the stacked bodies LMa and LMb.

Similarly to FIGS. 4A to 6C described above, FIGS. 10A to 13B show a cross-sectional portion that is a cross section of the contact region ER in the middle of manufacturing along the X direction and that corresponds to the cross section taken along line B-B of FIG. 2C described above. Even in FIGS. 10A to 13B, for convenience of description, for example, instead of the stacked bodies LMa and LMb each including the five layers of word lines WL, an example is shown in which the contact holes CLi to CLp respectively reaching the depth position of the eight insulating layers NL of the stacked body LMsb are mainly formed. As described above, even when the number of layers of the word lines WL is different, there is no difference in the formation method itself of various configurations including the contact holes CLi to CLp. In addition, in FIGS. 10A to 13B, the plurality of columnar portions HR are not shown.

FIGS. 10A to 13A show cross sections in which the contact holes CLi to CLp that respectively reach the height positions of the insulating layer NL of the stacked body LMsb are formed later. FIGS. 10A to 13B show cross sections in which a plurality of contact holes CLa to CLh are formed by the above-described processing of FIGS. 4A to 6C.

That is, FIGS. 10A to 13A show the state in which the configuration that is to be a part of the contact CC is formed, the contact CC being connected to one word line WL of the stacked body LMb. FIGS. 10A to 13B show the state in which the configuration that is to be a part of the contact CC is formed, the contact CC being connected to one word line WL of the stacked body LMa.

By the processing of FIGS. 7A to 7C described above, the insulating layer 56s is formed in the contact holes CLa to CLh, and the sacrificial layer 28 fills therein. Therefore, in FIG. 10B, it is assumed that a plurality of columnar bodies CSa to CSh, which are temporary structures, are formed.

As shown in FIGS. 10A and 10B, a hard mask pattern 82 having a plurality of openings is formed on the upper surface of the stacked body LMsb. Similarly to the hard mask pattern 81 described above, the hard mask pattern 82 is also an inorganic layer that is not removed by ashing using, for example, oxygen plasma. Each of the plurality of openings of the hard mask pattern 82 has, for example, a hole shape.

In addition, the upper surface of the stacked body LMsb exposed from the opening of the hard mask pattern 82 is etched to remove the uppermost insulating layer OL. As a result, a plurality of contact holes CLp that penetrate the uppermost insulating layer OL and reach the insulating layer NL immediately below the insulating layer OL are formed.

In the region in which the plurality of columnar bodies CSa to CSh are formed, the plurality of openings of the hard mask pattern 82 and the plurality of contact holes CLp are formed at positions overlapping with the columnar bodies CSa to CSh in the stacking direction.

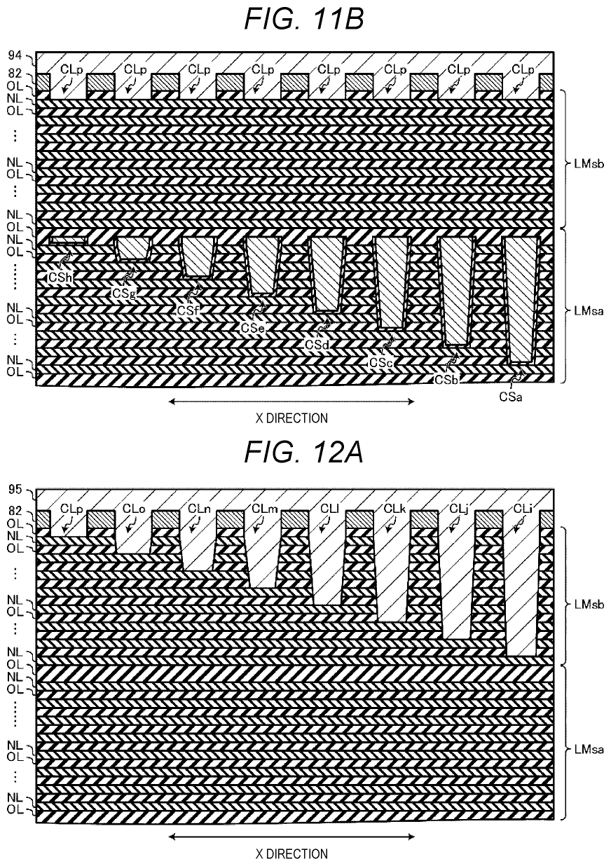

As shown in FIG. 11A, a plurality of the contact holes CLp to CLi respectively reaching the eight insulating layers NL in the stacked body LMsb are formed by the same processing as the processing shown in FIGS. 4C to 6C described above. The contact holes CLp to CLi have a tapered shape or a bowing shape, and the lower end portions thereof have a diameter smaller than the upper end portions.

As shown in FIG. 11B, while the plurality of contact holes CLp to CLi are formed, the region in which the plurality of columnar bodies CSa to CSh are formed is protected by covering the opening of the hard mask pattern 82 and the plurality of contact holes CLp with the resist pattern 94 and the like.

After the plurality of contact holes CLp to CLi are formed, the resist pattern 94 and the like are removed by ashing using oxygen plasma or the like.

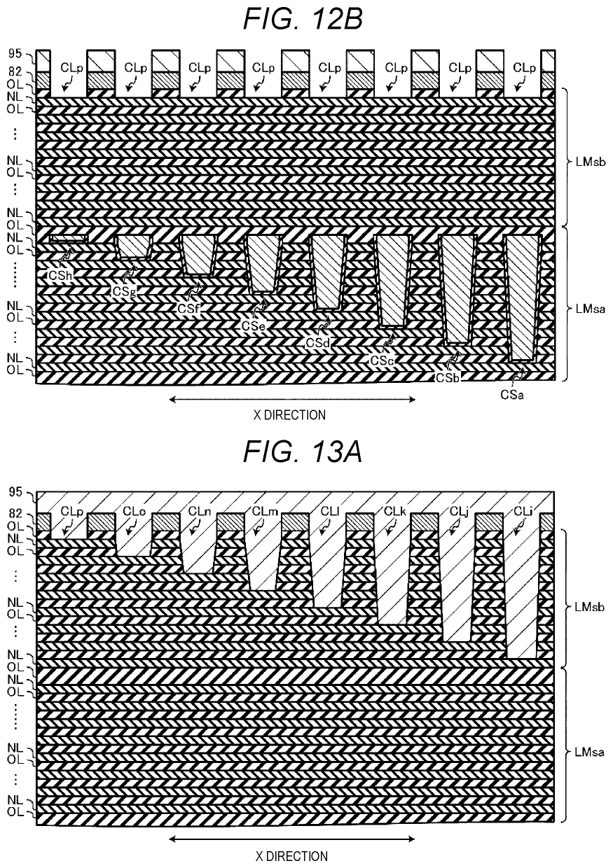

As shown in FIGS. 12A and 12B, a resist pattern 95 having a plurality of openings is formed. The resist pattern 95 partially covers the upper surface of the stacked body LMsb via the hard mask pattern 82. In the region in which the plurality of columnar bodies CSa to CSh are formed, the plurality of contact holes CLp are exposed from the opening of the resist pattern 95. In addition, the resist pattern 95 covers the entire region in which the plurality of contact holes CLp to CLi are formed.

As shown in FIG. 13B, the contact hole CLp exposed from the opening of the resist pattern 95 is etched to form the contact holes CLt. The contact holes CLt penetrate the stacked body LMsb and reach the upper end portions of the plurality of columnar bodies CSa to CSh formed in the stacked body LMsa, respectively. The contact holes CLt have a tapered shape or a bowing shape, and the lower end portions thereof have a diameter smaller than the upper end portions.

As shown in FIG. 13A, at this time, the plurality of contact holes CLp to CLi are protected by the resist pattern 95. Therefore, these contact holes CLp to CLi are not affected by the processing of FIG. 13B.

Thereafter, the resist pattern 95 is removed by ashing using oxygen plasma or the like. In addition, the hard mask pattern 82 is removed by etching or the like. In addition, the sacrificial layer 28 is removed from the columnar bodies CSa to CSh connected to the lower end portions of the contact holes CLt through the plurality of contact holes CLt.

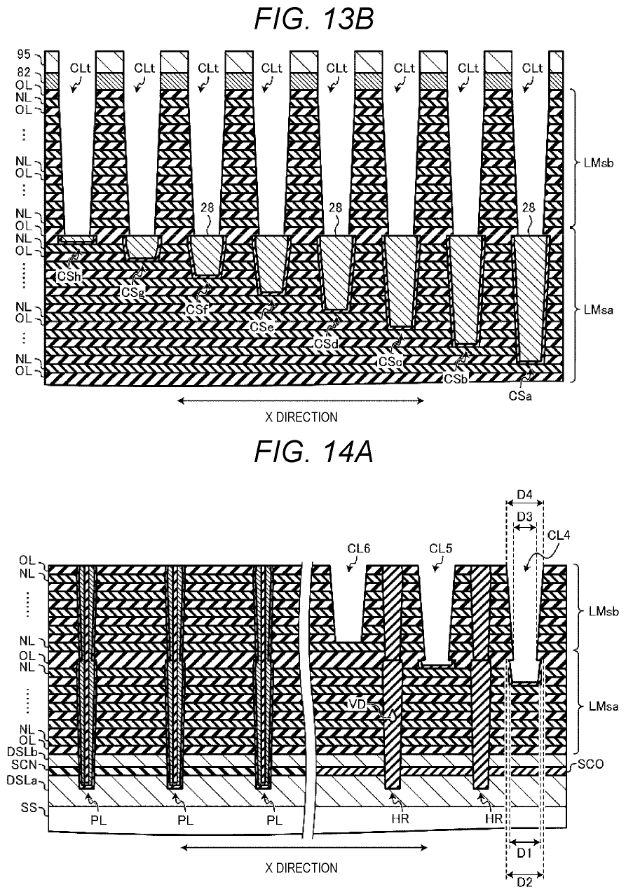

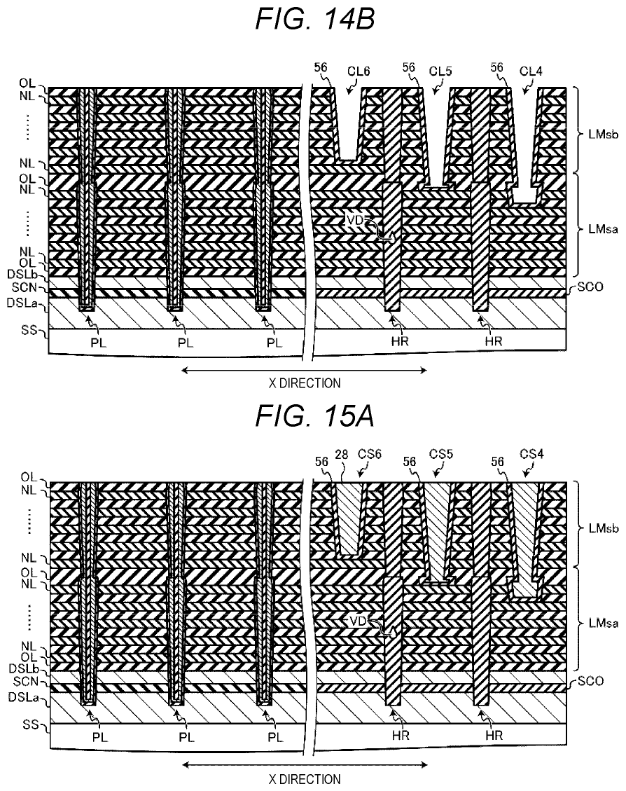

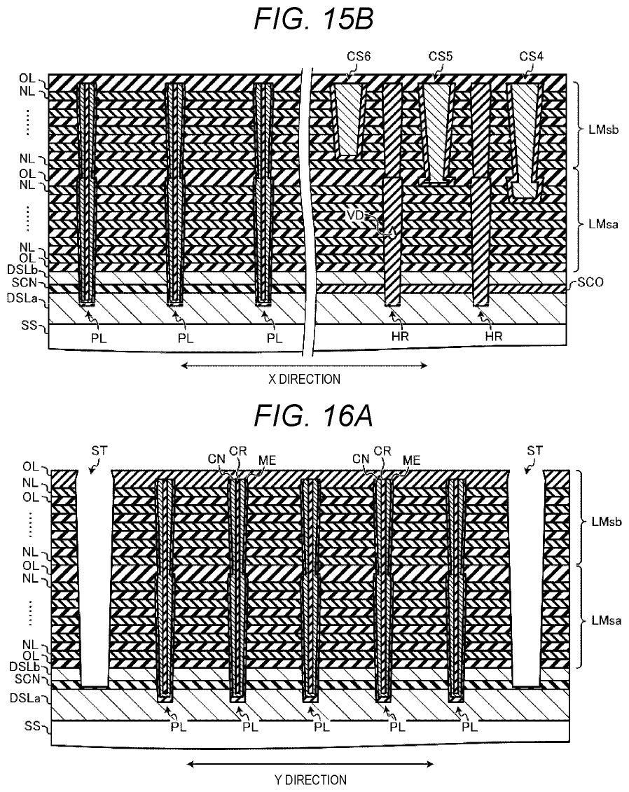

Similarly to FIGS. 7A to 9B, and the like, FIGS. 14A to 15B show a cross-sectional portion that is a cross section of the semiconductor storage device 1 under manufacturing along the X direction and that corresponds to the cross section taken along line A-A and the cross section taken along line A′-A′ of FIG. 2C described above. By the processing of FIGS. 10A to 13B described above, a plurality of contact holes are formed in the stacked bodies LMsa and LMsb in a region that is to be the contact region ER.

FIG. 14A shows the contact hole CL6 reaching the lowermost insulating layer NL of the stacked body LMsb, the contact hole CL5 reaching the fifth insulating layer NL from the lowermost insulating layer NL of the stacked body LMsa, and the contact hole CL4 reaching the fourth insulating layer NL from the lowermost insulating layer NL, among the plurality of contact holes respectively reaching the different insulating layers NL in the stacked bodies LMsa and LMsb.

Among these, the contact holes CL5 and CL4 are contact holes that penetrate the stacked body LMsb and that are respectively connected to the contact holes LCL5 and LCL4 formed in the stacked body LMsa in the uppermost insulating layer OL of the stacked body LMsa by the processing of FIG. 13B described above. Therefore, the diameters of the contact holes CL5 and CL4 change discontinuously in the uppermost insulating layer OL of the stacked body LMsa. In addition, the contact holes CL5 and CL4 have a step in the uppermost insulating layer OL of the stacked body LMsa.

That is, among the plurality of contact holes including the contact holes CL6 to CL4, a portion that extends in the stacked body LMsb has a tapered shape in which the cross-sectional area in the XY plane at the upper end portion is maximized, or a bowing shape in which the cross-sectional area between the upper end portion and the lower end portion is maximized. Here, the lower end portion of the portion extending in the stacked body LMsb, such as the contact holes CL6 to CL4, is a lower end portion in the stacked body LMsb, such as the contact hole CL6, or a connection portion with the portion that is present in the uppermost insulating layer OL of the stacked body LMsa and that extends in the stacked body LMsa, such as the contact holes CL5 and CL4.

In addition, among the plurality of contact holes including the contact holes CL6 to CL4, a portion corresponding to the contact holes LCL5 and LCL4, and the like and extending in the stacked body LMsa also has, as described above, in the uppermost insulating layer OL of the stacked body LMsa, a tapered shape in which the cross-sectional area in the XY plane at the upper end portion connected to the portion extending in the stacked body LMsb is maximized, or a bowing shape in which the cross-sectional area between the upper end portion and the lower end portion is maximized.

That is, in the example of FIG. 14A, for example, in the contact hole CL4, the diameter D3 of the lower end portion of the portion extending in the stacked body LMsb is smaller than the diameter D4 of the upper end portion. In the contact hole CL4, the diameter D4, which is the maximum diameter of the portion extending in the stacked body LMsb, may be located between the upper end portion and the lower end portion of the portion extending in the stacked body LMsb. In addition, in the contact hole CL4, the diameter D1 of the lower end portion of the portion extending in the stacked body LMsa is smaller than the diameter D2 of the upper end portion, as described above. In the contact hole CL4, the diameter D2, which is the maximum diameter of the portion extending in the stacked body LMsa, may be located between the upper end portion and the lower end portion of the portion extending in the stacked body LMsa.

In addition, as described above, the sacrificial layer 28 is removed from the contact holes LCL5 and LCL4. In addition, a part of the insulating layer 56s may remain on the side walls and the bottom surfaces of the contact holes LCL5 and LCL4, or the entire insulating layer 56s may be removed when the sacrificial layer 28 is removed.

As shown in FIG. 14B, an insulating layer 56 is formed on the side walls and the bottom surfaces of each of the plurality of contact holes including the contact holes CL6 to CL4. The insulating layer 56 is the insulating layer 56 shown in FIG. 2AB and the like described above. The insulating layer 56 has a layer thickness that may sufficiently withstand the voltage applied to the word lines WL after the word lines WL are formed in the stacked bodies LMsa and LMsb.

That is, the sacrificial layer 28 is once removed from the columnar bodies LCS5 and LCS4, and the like formed in FIG. 7B described above, and the insulating layer 56 is continuously formed in the contact holes LCL5 and LCL4. As a result, a structure that may sufficiently withstand the voltage applied to the word line WL to be formed later is obtained.

In addition, the sacrificial layer 28 such as an amorphous silicon layer fills again the plurality of contact holes including the contact holes CL6 to CL4. Accordingly, as shown in FIG. 15A, a columnar body including the columnar bodies CS6, CS5, and CS4 is formed from each of the plurality of contact holes. The columnar bodies CS6 to CS4, and the like are temporary contact structures including the sacrificial layer 28.

As shown in FIG. 15B, a silicon oxide layer or the like is further stacked on the upper surface of the stacked body LMsb. As a result, the uppermost insulating layer OL of the stacked body LMsb is thicker than the other insulating layers OL of the stacked body LMsb. In addition, the upper end portions of the columnar bodies CS6 to CS4, and the like are buried in the uppermost insulating layer OL.

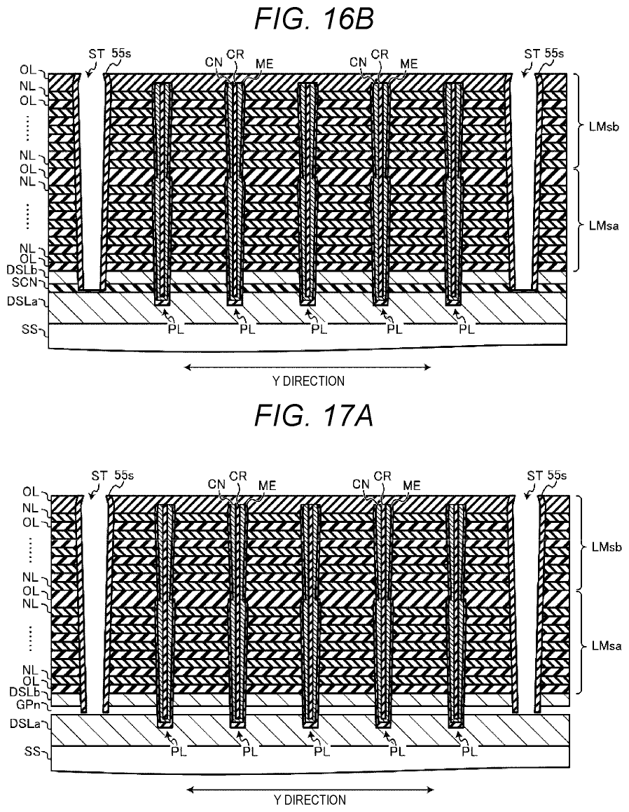

Next, a state in which the source line SL and the word line WL are formed will be described with reference to FIGS. 16A to 19B. FIGS. 16A to 19B are sectional views along the Y direction of a region that is to be the memory region MR, and show cross-sectional portions corresponding to the cross section taken along line C-C of FIG. 2C described above.

As shown in FIG. 16A, a slit ST that penetrates the stacked bodies LMsa and LMsb and the upper source line DSLb and reaches the intermediate sacrificial layer SCN is formed.

The slit ST has a tapered or bowing cross-sectional shape in the Y direction and also extends in the stacked bodies LMsa and LMsb in the direction along the X direction. Therefore, in the region that is to be the contact region ER, the lower end portion of the slit ST reaches the intermediate insulating layer SCO. The slit ST is used for a replacement processing described below and is to be a plate-shaped contact LI.

As shown in FIG. 16B, the insulating layer 55s is formed on the side wall of the slit ST facing the Y direction. The insulating layer 55s is, for example, a silicon oxide layer. The insulating layer 55s is a temporary protective layer that protects the stacked bodies LMsa and LMsb in the subsequent processing, unlike the above-mentioned insulating layer 55 (see FIG. 2AA) which is provided on the side wall of the plate-shaped contact LI.

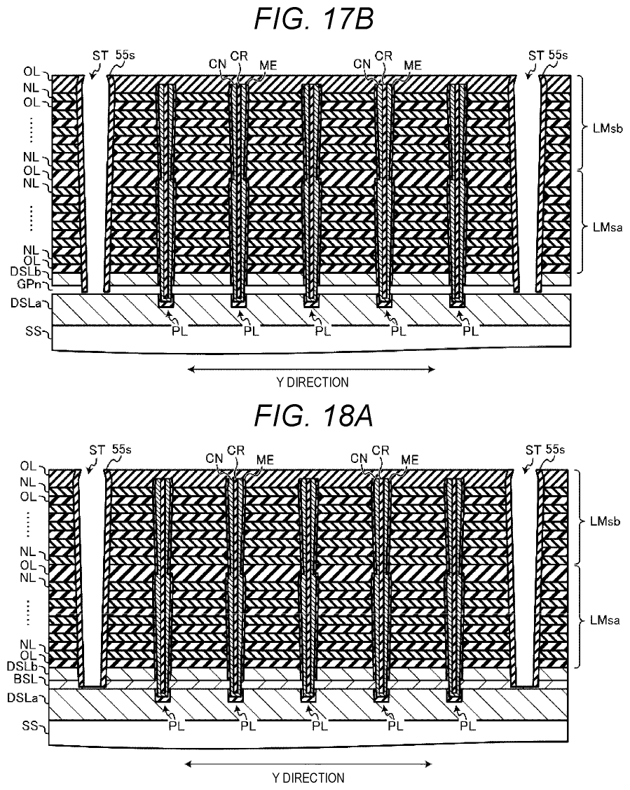

As shown in FIG. 17A, for example, a hot phosphoric acid is caused to flow through the slit ST with side wall protected by the insulating layer 55s to remove the intermediate sacrificial layer SCN interposed between the lower source line DSLa and the upper source line DSLb.

Accordingly, the gap layer GPn is formed between the lower source line DSLa and the upper source line DSLb. In addition, a part of the memory layer ME at the outer peripheral portion of the pillar PL is exposed in the gap layer GPn.

At this time, since the side wall of the slit ST is protected by the insulating layer 55s, it is prevented that the insulating layer NL in the stacked bodies LMsa and LMsb is also removed.

As shown in FIG. 17B, a chemical solution is allowed to flow into the gap layer GPn through the slit ST, and the memory layer ME exposed in the gap layer GPn is removed. Accordingly, the memory layer ME is removed from a part of the side wall of the pillar PL, and a part of the inner channel layer CN is exposed in the gap layer GPn.

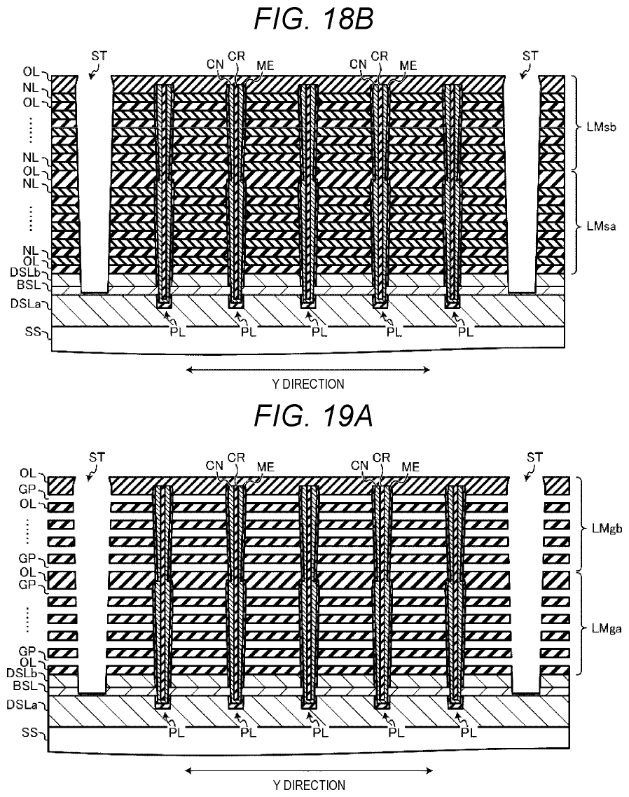

As shown in FIG. 18A, a raw material gas such as amorphous silicon is injected from the slit ST with the side wall protected by the insulating layer 55s, and the gap layer GPn is filled with amorphous silicon or the like. In addition, the supporting substrate SS is heat-treated to make the amorphous silicon that fills the gap layer GPn polycrystalline, thereby forming the intermediate source line BSL containing polysilicon or the like.

Accordingly, a part of the channel layer CN of the pillar PL is connected to the source line SL on the side surface through the intermediate source line BSL.

As shown in FIG. 18B, the insulating layer 55s is removed from the side wall of the slit ST.

In the region that is to be the contact region ER, the intermediate insulating layer SCO is formed between the lower source line DSLa and the upper source line DSLb instead of the intermediate sacrificial layer SCN. Therefore, in the region that is to be the contact region ER, the source line SL is not affected by the processing shown in FIGS. 16A to 18B described above.

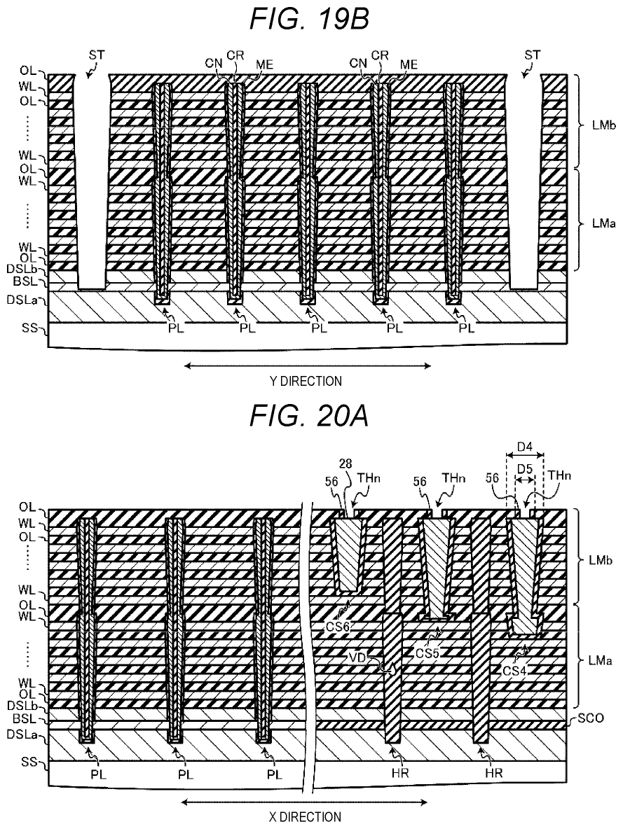

As shown in FIG. 19A, a hot phosphoric acid is caused to flow from the slit ST into the stacked bodies LMsa and LMsb to remove the insulating layer NL of the stacked bodies LMsa and LMsb. As a result, stacked bodies LMga and LMgb having the plurality of gap layers GP from which the insulating layer NL between the insulating layers OL is removed are formed.

The stacked bodies LMga and LMgb including the plurality of gap layers GP have a fragile structure. In the region that is to be the memory region MR, the plurality of pillars PL support the fragile stacked bodies LMga and LMgb. Meanwhile, in the region that is to be the contact region ER, the plurality of columnar portions HR support the stacked bodies LMga and LMgb.

With the support structure of the pillar PL and the columnar portion HR, the remaining insulating layer OL can be prevented from being bent, and the stacked bodies LMga and LMgb themselves can be prevented from being distorted or collapsed.

As shown in FIG. 19B, a raw material gas of a conductive material such as tungsten or molybdenum is injected from the slit ST into the stacked bodies LMga and LMgb, and the gap layers GP of the stacked bodies LMga and LMgb are filled with the conductive material to form a plurality of word lines WL and the like. As a result, the stacked body LM is formed, which includes stacked bodies LMa and LMb in which a plurality of word lines WL and the like and a plurality of insulating layers OL are alternately stacked one by one.

As described above, the processing of forming the intermediate source line BSL from the intermediate sacrificial layer SCN and the processing of forming the word line WL from the insulating layer NL are also referred to as replacement processing.

Thereafter, the insulating layer 55 is formed on the side wall of the slit ST, and the conductive layer 25 fills the insulating layer 55 to form the plate-shaped contact LI serving as the source line contact. Alternatively, the insulating layer 55 or the like may fill the slit ST without forming the conductive layer 25 to form a plate-shaped member having no function as a source line contact.

Next, the state in which the upper layer wiring M0 connected to the contact CC via the plurality of contacts CC and the plug V0 is formed is shown in FIGS. 20A to 24B. Similarly to FIGS. 14A to 15B, and the like, FIGS. 20A to 24B show a cross-sectional portion that is a cross section of the semiconductor storage device 1 under manufacturing along the X direction and that corresponds to the cross section taken along line A-A and the cross section taken along line A′-A′ of FIG. 2C described above.

As shown in FIG. 20A, a plurality of through-holes THn are formed. The plurality of through-holes THn penetrate an upper portion of the uppermost insulating layer OL of the stacked body LMb and are connected to the plurality of columnar bodies including the columnar bodies CS4 to CS6 disposed in the insulating layer OL, respectively. The through-holes THn are to be neck portions CCn of the contacts CC. That is, the diameter D5 of the through-holes THn is smaller than the diameter D4 of the upper end portions of the plurality of contact holes including the contact holes CL6 to CL4.

In addition, the insulating layer 56 that covers each of the side walls and the bottom surfaces of the through-holes THn is formed. Further, the insulating layer 56 is removed from each bottom surface of the through-holes THn. Alternatively, since the neck portion CCn formed from the through-hole THn is disposed in the insulating layer OL, the insulating layer 56 does not need to be formed on the side wall of the through-hole THn.

As shown in FIG. 20B, the sacrificial layer 28 is removed from each of the plurality of columnar bodies connected to the lower end portions of the plurality of through-holes THn through the plurality of through-holes THn. As a result, a plurality of contact holes including the contact holes TH4 to TH6 that respectively reach the word lines WL to be connected from the upper surface of the stacked body LMb are formed.

The contact holes TH4 to TH6, and the like include the contact holes CL4 to CL6, and the like extending in the stacked bodies LMa and LMb, which are shown in FIGS. 14A and 14B described above, and the through-holes THn connected to the contact holes CL4 to CL6, and the like, respectively. In addition, an insulating layer 56 is formed on the side walls and the bottom surfaces of the portions extending in the stacked bodies LMa and LMb, such as the contact holes TH4 to TH6, to continuously cover the side walls and the bottom surfaces.

Meanwhile, the through-hole THn penetrating the upper portion of the uppermost insulating layer OL of the stacked body LMb may be formed before the replacement processing of the stacked bodies LMsa and LMsb, for example, after the processing of FIG. 14A described above.

In this case, by the subsequent processing shown in FIG. 14B, the insulating layer 56 that continuously covers the through-hole THn and the contact holes CL4 to CL6, and the like extending in the stacked bodies LMsa and LMsb is formed. At this time, the insulating layer 56 also covers the stepped portion between the lower end portion of the through-hole THn connected in the uppermost insulating layer OL of the stacked body LMsb and the upper end portions of the contact holes CL4 to CL6, and the like.

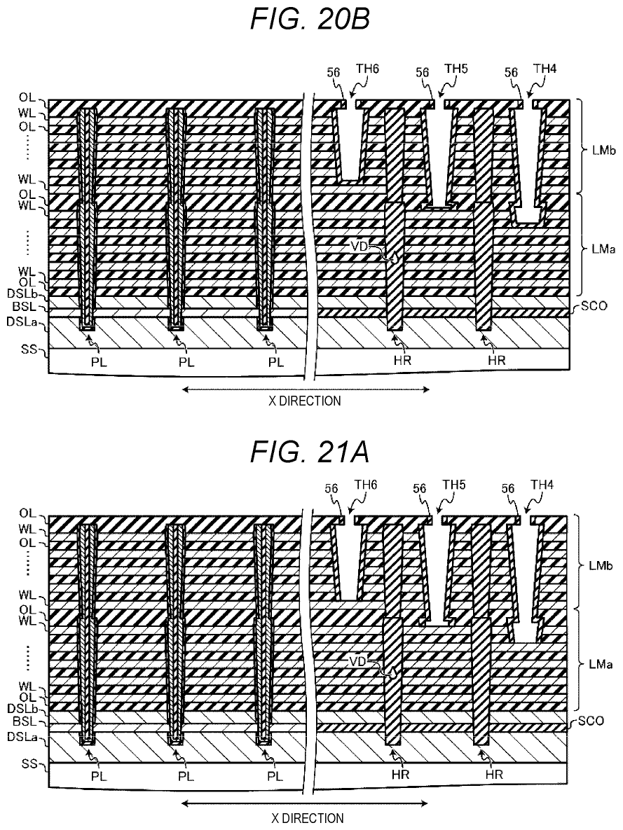

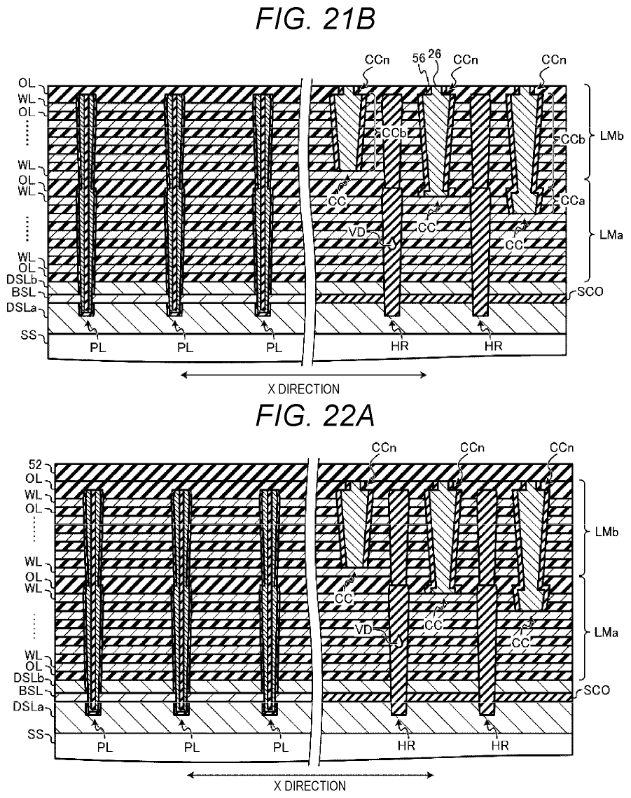

As shown in FIG. 21A, the insulating layer 56 is removed from the bottom surfaces of the plurality of contact holes including the contact holes TH4 to TH6. The bottom surface of the contact hole may be simply referred to as a hole bottom or the like. It is desirable that the insulating layer 56 is removed by highly anisotropic etching such as reactive ion etching (RIE) using plasma, for example. Accordingly, the insulating layer 56 at the bottom of the hole can be more reliably removed.

As shown in FIG. 21B, the conductive layer 26 fills the plurality of contact holes including the contact holes TH4 to TH6. Accordingly, a plurality of contacts CC having the conductive layers 26 that continuously extend in the contact holes TH4 to TH6, and the like from the upper end portion to the lower end portion and that are respectively connected to the word lines WL to be connected are formed.

Among the plurality of contacts CC, each contact CC that connects to any word line WL in the stacked body LMa is provided with the neck portion CCn disposed in the uppermost insulating layer OL of the stacked body LMb, the contact portion CCb that penetrates the stacked body LMb, and the contact portion CCa that extends in the stacked body LMa and that reaches the word line WL to be connected.

In addition, each contact CC that connects to any word line WL in the stacked body LMb is provided with the neck portion CCn disposed in the uppermost insulating layer OL of the stacked body LMb, and the contact portion CCb that extends in the stacked body LMb and that reaches the word line WL to be connected.

The above-described processing of forming the contact CC by filling the inside of the contact holes TH4 to TH6, and the like with the conductive layer 26 and the processing of forming the plate-shaped contact LI by filling the above-described slit ST with the conductive layer 25 may be collectively performed.

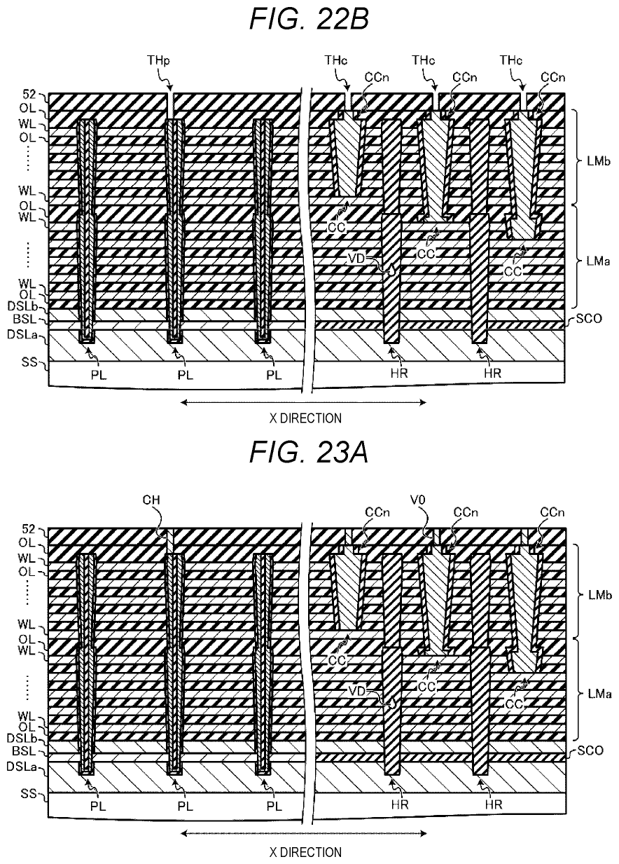

As shown in FIG. 22A, an insulating layer 52 is formed on the upper surface of the stacked body LMb.

As shown in FIG. 22B, a plurality of through-holes THc that penetrate the insulating layer 52 and respectively reach the upper end portions of the plurality of contacts CC, that is, the neck portions CCn provided in the plurality of contacts CC are formed. In addition, a plurality of through-holes THp that penetrate the insulating layer 52 and respectively reach the upper end portions of the plurality of pillars PL are formed. In the cross section shown in FIG. 22B, a through-hole THp formed on the central pillar PL among the three pillars PL is shown.

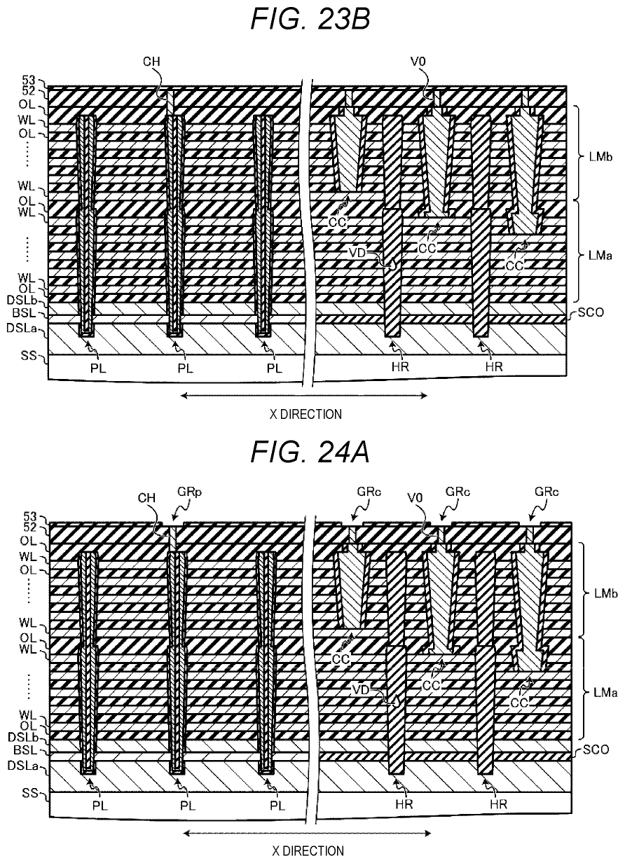

As shown in FIG. 23A, the through-hole THc is filled with the conductive layer to form a plurality of plugs V0. More specifically, the barrier metal layer 27b (see FIG. 2AD) covering the side wall and the bottom surface of the through-hole THc is formed, and the conductive layer 27 (see FIG. 2AD) fills the barrier metal layer 27b, whereby the plug V0 is formed. Accordingly, the barrier metal layer 27b is interposed between the conductive layer 26 of the contact CC and the conductive layer 27 of the plug V0.

Similarly, the barrier metal layer is formed in the through-hole THp, and the conductive layer further fills therein to form a plurality of plugs CH. The barrier metal layer and the conductive layer formed in the through-hole THp are formed of the same material as the barrier metal layer 27b and the conductive layer 27 formed in the through-hole THc described above.

As shown in FIG. 23B, the insulating layer 53 is formed on the insulating layer 52. At this time, the thickness of the insulating layer 53 can be set to the thickness of the upper layer wiring M0 to be formed later.

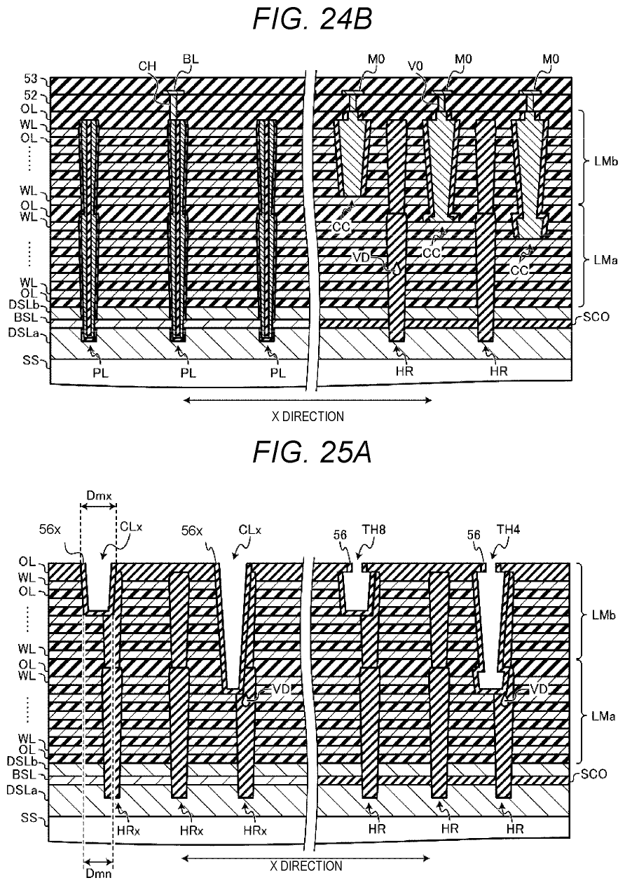

As shown in FIG. 24A, a plurality of the through-grooves GRc which penetrate the insulating layer 53 and in which the upper end portions of the plurality of plugs V0 are respectively exposed on the bottom surface are formed. In addition, a plurality of the through-grooves GRp which penetrate the insulating layer 53 and in which the upper end portions of the plurality of plugs CH are respectively exposed on the bottom surface are formed.

As shown in FIG. 24B, a plurality of upper layer wirings M0, which are connected to the plurality of plugs V0 by filling the through-groove GRc with the conductive layer, respectively, are formed. Similarly, a plurality of bit lines BL are formed, which are connected to the plurality of plugs CH by filling the through-groove GRp with the conductive layer, respectively.

As described above, the plug V0 and the upper layer wiring M0, and the plug CH and the bit line BL connected to the pillar PL are formed in parallel. In addition, for example, the plug V0 and the upper layer wiring M0, and the plug CH and the bit line BL, and the like may be collectively formed by using a dual damascene method or the like.

Meanwhile, the peripheral circuit CBA is formed on the semiconductor substrate SB, which is a separate body from the supporting substrate SS on which the stacked body LM is formed, and is covered with the insulating layer 40. In the insulating layer 40, a contact, a via, wiring, or the like for drawing out the peripheral circuit CBA to the surface of the insulating layer 40 is formed, and the contact, the via, the wiring, or the like is connected to the electrode pad PDc or the like formed on the upper surface of the insulating layer 40.

In addition, the supporting substrate SS and the semiconductor substrate SB are bonded to each other by the insulating layers 50 and 40 thereof, respectively, and the electrode pads PDb and PDc are connected in the insulating layers 50 and 40. Thereafter, the supporting substrate SS is ground and removed to expose the source line SL, and the electrode film EL is connected through the insulating layer 60 in which the plug PG is formed.

As described above, the semiconductor storage device 1 of the embodiment is manufactured.

### Overview

A semiconductor storage device such as a three-dimensional nonvolatile memory has a configuration in which, for example, a memory cell is formed three-dimensionally in a stacked body in which a plurality of word lines are stacked. In order to establish an electrical connection to these word lines to the upper layer wiring and the like, contacts connected to the individual word lines are formed. When forming a contact, in order to prevent a short circuit with a word line or the like that is not to be connected, an insulating layer is formed on the side wall and the bottom surface of the contact hole, and the conductive layer is filled therein after removing the insulating layer on the bottom surface. In this manner, the contact is connected to a word line that is to be connected.

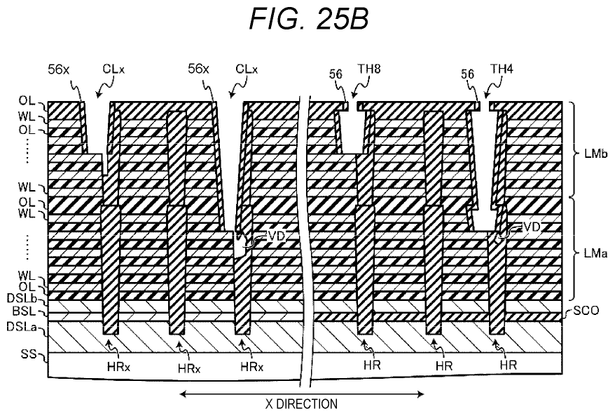

Meanwhile, a plurality of columnar portions are disposed in the contact region in which the plurality of contacts are disposed in order to support the stacked body being replaced. The plurality of columnar portions are disposed at a pitch smaller than, for example, the diameter of the contact such that the stacked body may be sufficiently supported, and the contact hole is formed while etching and removing a part of the plurality of columnar portions. In this case, a problem may occur due to a processing of removing the insulating layer from the bottom surfaces of the plurality of contact holes having different height positions in the stacked body. This point will be described with reference to FIGS. 25A and 25B.

FIGS. 25A and 25B are sectional views along the X direction showing a state in which the insulating layers 56 and 56x are removed from the bottom surfaces of the contact holes TH4, TH8, and CLx according to the embodiment and the comparative example, respectively. The left side of the paper surface of FIGS. 25A and 25B shows the processing with respect to the contact hole CLx of the comparative example, and the right side of the paper surface shows the processing with respect to the contact holes TH4 and TH8 of the embodiment.

As shown in FIGS. 25A and 25B, the contact holes TH4 and TH8 of the embodiment are formed in contact with the adjacent columnar portion HR. The contact hole CLx of the comparative example is also formed in contact with the adjacent columnar portion HRx. Accordingly, a part of the columnar portions HR and HRx is missing, and a part of the contact holes TH4, TH8, and CLx enters the missing portions of the columnar portions HR and HRx.

In addition, in the comparative example, the contact hole CLx connected to the word line WL in the stacked body LMb and the contact hole CLx connected to the word line WL in the stacked body LMa are both formed at once. That is, a plurality of contact holes CLx, which extend from the upper surface of the stacked body LMb before or after replacement to extend in the stacked body LMb or to further extend in the stacked body LMa by penetrating the stacked body LMb, are collectively formed.

As shown in FIG. 25A, the contact hole CLx of the comparative example has the maximum diameter Dmx at the upper end portion, which is open to the upper surface of the stacked body LMb, and has the minimum diameter Dmn at the lower end portion, which is the connection end to the word line WL, by the above-described formation method. That is, even in the contact hole CLx reaching the word line WL in the stacked body LMa, a diameter gradually changes in the uppermost insulating layer OL of the stacked body LMa, and a step or the like is not provided.

In addition, the side wall and the bottom surface of the contact hole CLx are covered with the insulating layer 56x.

As shown in FIG. 25B, the insulating layer 56x is removed from the bottom surface of the contact hole CLx of the comparative example. At this time, for example, anisotropic etching such as RIE is used so that the insulating layer 56x may be more reliably removed even from the bottom surface of the deep contact hole CLx.

For example, the contact hole CLx reaching the eighth word line WL from the lowermost layer has a bottom surface at a relatively shallow position of the stacked body LMb. Therefore, when the contact with the columnar portion HRx occurs, the etching may proceed in the columnar portion HRx, which is made of the silicon oxide layer or the like the insulating layer 56x, in the depth direction even after the insulating layer 56x on the bottom surface is removed.

The same thing as described above may also occur in the contact hole CLx connected to the word line WL of the upper layer in the stacked body LMa. For example, the contact hole CLx reaching the fourth word line WL from the lowermost layer has a bottom surface at a relatively shallow position of the stacked body LMa as compared with the contact hole connected to the word line WL of the lower layer in the stacked body LMa. Therefore, when the contact with the columnar portion HRx occurs, even in such a contact hole CLx, after the insulating layer 56x on the bottom surface is removed, etching may proceed in the columnar portion HRx in the depth direction.

In addition, for example, when the void VD generated in the columnar portion HRx is in close proximity to the contact portion with the contact hole CLx, the etching in the columnar portion HRx in the depth direction as described above may be promoted.

As described above, when the columnar portion HRx is etched in the depth direction, the conductive layer extending in the columnar portion HRx in the depth direction is formed in the columnar portion HRx when the contact hole CLx is filled with the conductive layer. Accordingly, there is a possibility that the conductive layer of the contact may extend to the height position of the word line WL of the lower layer of the word line WL to be connected via the columnar portion HRx. That is, a short circuit may occur between the plurality of word lines WL.

As shown in FIG. 25A, all of the contact holes of the embodiment have a portion in which the diameter is narrowed at the upper end portion, such as the contact holes TH4 and TH8. That is, all of the contact holes of the embodiment have the through-hole THn formed by the processing shown in FIG. 20A described above. In addition, the contact hole of the embodiment, which reaches the word line WL of the stacked body LMa, such as the contact hole TH4 to be connected to the fourth word line WL from the lowermost layer, has a stepped portion having a diameter that discontinuously changes in the uppermost insulating layer OL of the stacked body LMa.

Accordingly, for example, in the contact hole TH8 or the like, the ion bombardment by RIE is softened and more precisely directed at the hole bottom due to the narrow portion provided at the upper end portion. In addition, for example, in the contact hole TH4 or the like, the ion bombardment by RIE is also softened and more precisely directed at the hole bottom due to the step provided in the uppermost insulating layer OL of the stacked body LMa in addition to the narrow portion of the upper end portion. Therefore, in these contact holes TH4 and TH8, and the like, etching in the columnar portion HR in the depth direction after the insulating layer 56 is removed is unlikely to occur.

According to the semiconductor storage device 1 of the embodiment, the contact CC includes the contact portion CCa that extends in the stacked body LMa and that is connected to the word line WL to be connected at the lower end portion among the plurality of word lines WL of the stacked body LMa, and the contact portion CCb that extends in the stacked body LMb and is connected to the upper end portion of the contact portion CCa and in which the diameter of the lower end portion is smaller than the diameter of the upper end portion of the contact portion CCa.

Accordingly, even though contact with the columnar portion HR occurs, the etching of the columnar portion HR when the insulating layer 56 is removed from the hole bottom is unlikely to occur. With the above configuration, it is possible to prevent the short circuit between the plurality of word lines WL in the stacked body LMa.

In the contact CC, the fact that the contact CC has two kinds of diameters that discontinuously change in the insulating layer OL disposed near the center of the stacked body LM in the stacking direction, one diameter is located close to the lower surface of the insulating layer OL, and the other diameter is smaller than the one diameter and is located close to the upper surface of the insulating layer OL proves that the contact CC has at least the contact portions CCa and CCb.

According to the semiconductor storage device 1 of the embodiment, the contact portion CCa has the lower end portion having a diameter smaller than a diameter of the upper end portion connected to the contact portion CCb. The contact portion CCb has an upper end portion having a diameter larger than a diameter of a lower end portion connected to the contact portion CCa. For example, by configuring each of the contact portions CCa and CCb in this way, the contact CC having a step in the middle in the extension direction can be obtained.

According to the semiconductor storage device 1 of the embodiment, the contact CC is connected to the upper end portion of the contact portion CCb, and further has the neck portion CCn in which the diameter of the lower end portion is smaller than the diameter of the upper end portion of the contact portion CCb. Accordingly, the contact CC also has a narrow portion at the upper end portion, and the etching of the columnar portion HR can be further suppressed.

According to the semiconductor storage device 1 of the embodiment, the contact CC that includes the contact portion CCb and the neck portion CCn, extends in the stacked body LMb outside the memory region MR in the stacking direction of the stacked body LMb, and is connected to one of the plurality of word lines WL of the stacked body LMb at the lower end portion of the contact portion CCb is further provided. As described above, even in the contact CC connected to a word line WL of the stacked body LMb, the etching of the columnar portion HR can be suppressed by providing the narrow portion at the upper end portion.

According to the semiconductor storage device 1 of the embodiment, the region in which the plurality of contacts CC of the stacked body LM are disposed is further provided with the plurality of columnar portions HR extending in the stacked body LM in the stacking direction of the stacked body LM and having a pitch narrower than the maximum diameter of the contact CC. In this way, the plurality of the columnar portions HR are disposed at a pitch narrower than the diameter of the contact CC while allowing the contact with the contact CC, so that the stacked bodies LMga and LMgb during replacement can be sufficiently firmly supported.

According to the method for manufacturing the semiconductor storage device 1 of the embodiment, the insulating layer 56 that continuously covers the side wall of the contact hole penetrating the stacked body LMsb and the side wall and the bottom surface of the contact extending in the stacked body LMsa is formed.

As described above, even when the contact portions CCa and CCb are individually formed, the insulating layer 56 that continuously covers the contact portions CCa and CCb is formed. As a result, a sufficient breakdown voltage between the contact CC extending in the stacked body LM and the word line WL that is not to be connected can be obtained.

### Other Modification Examples

In the above-described embodiment, it is assumed that all of the plurality of contacts CC have the neck portion CCn, but the present disclosure is not limited thereto. For example, at least one of the contacts CC connected to the word line WL of the stacked body LMb may have a neck portion CCn. For example, in addition to the contact CC connected to the word line WL of the stacked body LMb, at least one of the contacts CC connected to the word line WL of the stacked body LMa may have the neck portion CCn.

In addition, the neck portions CCn may not be provided in all of the plurality of contacts CC. For example, only the contacts CC connected to the word line WL of the stacked body LMb may be provided with the neck portion CCn, and none of the contacts CC connected to the word line WL of the stacked body LMa has the neck portion CCn.

As a result, in the contact hole connected to the word line WL in the stacked body LMb, a shielding effect against the hole bottom is obtained by the through-hole THn which is to be the neck portion CCn. Meanwhile, in the contact hole connected to the word line WL of the stacked body LMa, the diameter of the lower end portion of the contact hole extending in the stacked body LMb is narrowed, so that a shielding effect with respect to the hole bottom is still obtained.

In addition, as in the above-described embodiment, when all of the plurality of contacts CC have the neck portion CCn, both of the contact portions CCa and CCb may have the vertical shape. In this case, the contact CC connected to the word line WL in the stacked body LMa does not have a narrow portion having a reduced diameter at the connection portion between the contact portions CCa and CCb. Even in this case, the shielding effect with respect to the hole bottom is obtained in these contact holes by the through-hole THn at the upper end portion.

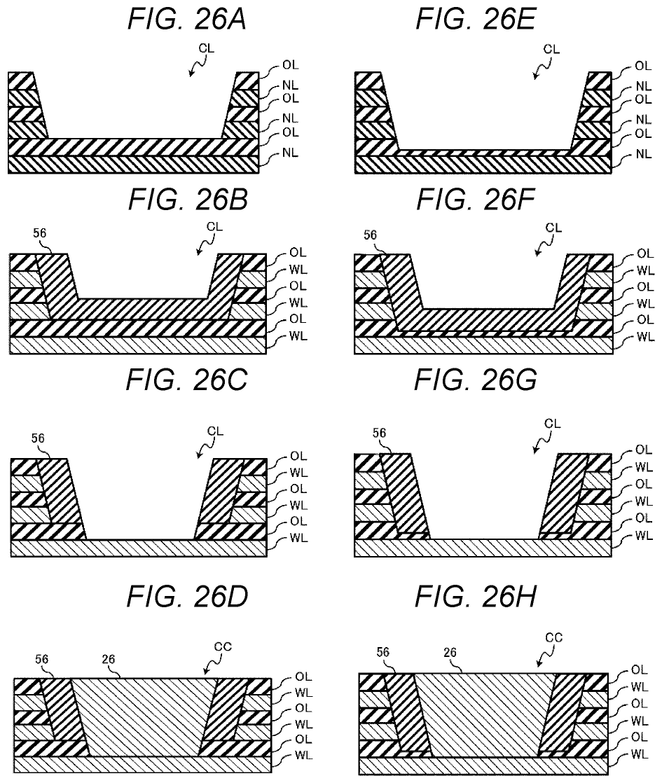

In addition, in the above-described embodiment, the individual contact holes reach the height position of the insulating layer NL, which is subjected to the replacement processing and is to be the word line WL to be connected. However, the contact hole may reach the insulating layer OL portion immediately above the insulating layer NL, which is to be the word line WL to be connected. In this case, when the insulating layer 56 at the hole bottom is removed, the contact hole can penetrate the insulating layer OL at the lower end portion to reach the word line WL to be connected. The example of this case is shown in FIGS. 26A to 26H.

FIGS. 26A to 26H are sectional views along the X direction showing a part of the procedure of the method for manufacturing a semiconductor storage device according to another modification example of the embodiment. As shown in FIGS. 26A to 26H, the final shape of the contact CC may be different depending on the selection ratio with respect to the base layer when forming the contact hole CL. In the example in FIGS. 26A to 26H, the base layer is the insulating layer OL immediately above the insulating layer NL, which is the final target to be reached of the contact hole CL.

FIGS. 26A to 26D are views showing an example in which the selection ratio with respect to the base layer when forming the contact hole CL is relatively high.

As shown in FIG. 26A, among the plurality of insulating layers NL and OL stacked alternately, the contact hole CL is formed with the height position of the lowermost insulating layer NL in the drawing as the final target to be reached. Meanwhile, in the present example, the insulating layer OL immediately above the insulating layer NL of the target to be reached is used as the stopper layer to form the contact hole CL. At this time, when the selection ratio of the insulating layer OL to the insulating layer NL is sufficiently high, the insulating layer OL is hardly etched and removed. Therefore, the bottom surface of the contact hole CL is located on the upper surface of the insulating layer OL.

FIG. 26B shows a state after the plurality of word lines WL are formed by replacing the plurality of insulating layers NL. An insulating layer 56 is formed on the side wall and the bottom surface of the contact hole CL.

As shown in FIG. 26C, the insulating layer 56 on the bottom surface of the contact hole CL is removed, and the contact hole CL is caused to penetrate the insulating layer OL under the insulating layer 56 to reach the word line WL of the lowermost layer in the drawing, which is the final target to be reached. At this time, the selection ratio between the insulating layer 56 and the insulating layer OL is low. Therefore, it is possible for the contact hole CL to penetrate the insulating layer OL under the insulating layer 56.

As shown in FIG. 26D, the conductive layer 26 fills the contact hole CL to form a contact CC.

As described above, by the processing of FIGS. 26A to 26D, the contact CC has the insulating layer 56 that reaches the upper surface of the insulating layer OL immediately above the word line WL to be connected. That is, the side wall portion of the conductive layer 26 extending in the insulating layer OL is not covered with the insulating layer 56.

FIGS. 26E to 26H are views showing an example in which the selection ratio with respect to the base layer when forming the contact hole CL is relatively low.

As shown in FIG. 26E, similarly to the above, the insulating layer OL immediately above the lowermost insulating layer NL in the drawing, which is the target to be reached, is used as a stopper layer to form the contact hole CL. At this time, when the selection ratio of the insulating layer OL to the insulating layer NL is relatively low, a part of the insulating layer OL is etched and removed in the layer thickness direction. Therefore, the bottom surface of the contact hole CL is located in the insulating layer OL.

FIG. 26F shows a state after the plurality of word lines WL are formed by replacing the plurality of insulating layers NL. An insulating layer 56 is formed on the side wall and the bottom surface of the contact hole CL.

As shown in FIG. 26G, the insulating layer 56 on the bottom surface of the contact hole CL is removed, and the contact hole CL is caused to penetrate the insulating layer OL under the insulating layer 56 to reach the word line WL of the lowermost layer in the drawing, which is the final target to be reached.

As shown in FIG. 26H, the conductive layer 26 fills the contact hole CL to form a contact CC.

As described above, by the processing of FIGS. 26E to 26H, the contact CC has the insulating layer 56 in which the lower end portion is located in the insulating layer OL immediately above the word line WL to be connected. That is, also in this case, the side wall portion of the conductive layer 26 extending downward from the predetermined position of the insulating layer OL immediately above the word line WL in the layer thickness direction is not covered with the insulating layer 56.

As described above, when the insulating layer OL is used as the stopper layer to form the contact hole CL, the lower end portion of the insulating layer 56 provided in the contact CC does not come into contact with the upper surface of the word line WL to be connected to the contact CC. In addition, the position of the lower end portion of the insulating layer 56 may be different in the layer thickness direction of the insulating layer OL immediately above the word line WL depending on the selection ratio or the like when forming the contact hole CL. It is preferable that the lower end portion of the insulating layer 56 reaches a height position of the upper surface of the insulating layer OL immediately above or a position lower than the height position of the upper surface of the insulating layer OL immediately above and higher than the height position of the lower surface.

As described above, the processing of the contact hole CL is temporarily stopped in the insulating layer OL immediately above the insulating layer NL, instead of using the insulating layer NL of the target to be reached as the stopper layer. Accordingly, when the contact hole CL is formed, the removal of a part of the insulating layer NL of the final target to be reached in the layer thickness direction is inhibited. Accordingly, after the replacement processing, it is possible to prevent the layer thickness of the word line WL to be connected from being reduced at the connection portion with the contact CC.

In addition, in the above-described embodiment, when forming the contact CC connected to the word line WL in the stacked body LMa, the contact hole reaching the insulating layer NL of the target to be reached from the uppermost surface of the stacked body LM is formed, then the insulating layer 56 is formed at once, and the insulating layer 56 on the bottom surface of the contact hole is removed.

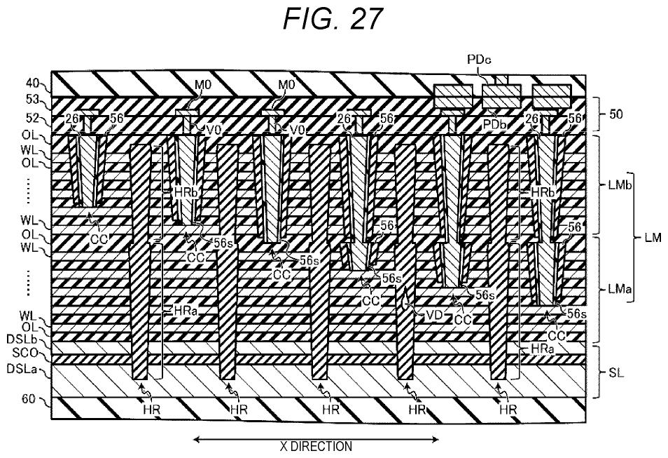

Meanwhile, the insulating layer 56 may be formed and removed from the hole bottom each time the contact hole extending in each of the stacked bodies LMa and LMb is formed. The example of this case is shown in FIGS. 27 to 36B.

FIG. 27 is a sectional view along the X direction showing an example of a configuration of a semiconductor storage device according to another modification example of the embodiment.

As shown in FIG. 27, the contact CC connected to the word line WL in the stacked body LMa includes the conductive layer 26 that continuously extends in the contact CC from the upper end portion to the lower end portion. In addition, the insulating layers 56 of the contacts CC cover the side wall portions of the conductive layer 26 extending in the stacked body LMa and the side wall portions of the conductive layer 26 extending in the stacked body LMb, respectively, after being temporarily interrupted in the uppermost insulating layer OL of the stacked body LMa.

In the example in FIG. 27, as described below, the insulating layer OL immediately above the insulating layer NL of the target to be reached is used as the stopper layer to form the contact hole, and thus a configuration in which the lower end portion of the insulating layer 56 is not in contact with the word line WL to which the contact CC in each of the stacked bodies LMa and LMb is to be connected is provided.

In the manufacturing method described below, each of the plurality of contacts CC further has the insulating layer 56s covering the side wall of the conductive layer 26 extending in the stacked body LMa. A lower end portion of the insulating layer 56s is in contact with an upper surface of the word line WL to be connected to the contact CC.

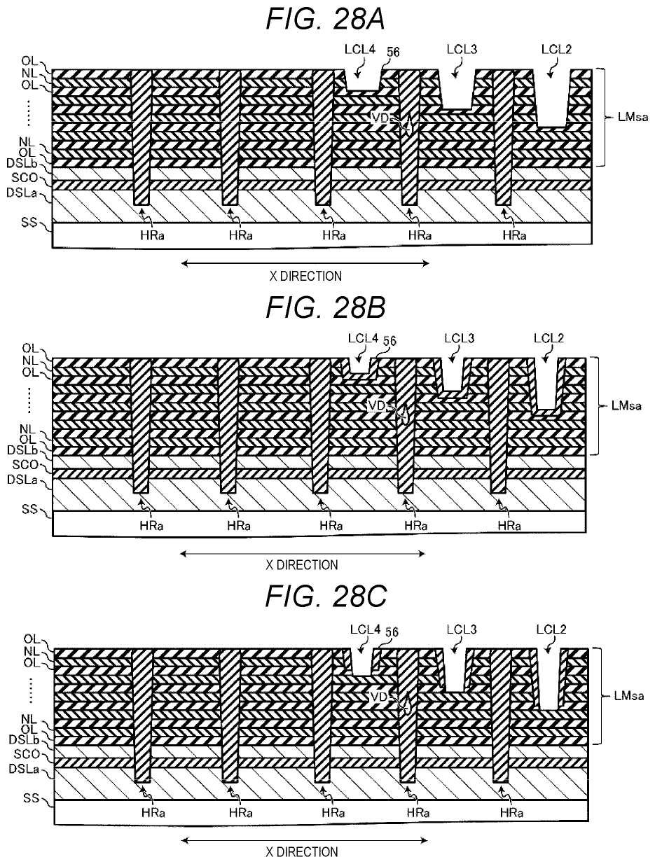

FIGS. 28A to 36B are sectional views along the X direction sequentially showing a part of the procedure of the method for manufacturing a semiconductor storage device according to the another modification example of the embodiment.

As shown in FIG. 28A, a columnar portion HRa is formed in a stacked body LMsa in which a plurality of insulating layers NL and OL are stacked. In this state, for example, using the method shown in FIGS. 4A to 6C of the embodiment described above, a plurality of contact holes are formed with individual insulating layers NL in the stacked body LMsa as a final target to be reached. FIG. 28A shows contact holes LCL2 to LCL4 that set the second to fourth insulating layers NL from the lowermost layer in the stacked body LMsa to the target to be reached among the plurality of contact holes.

In the example shown in FIG. 28A, the plurality of contact holes including the contact holes LCL2 to LCL4 are formed with the insulating layer OL immediately above the insulating layer NL of the target to be reached as the stopper layer. Therefore, in FIG. 28A, the bottom surfaces of the contact holes LCL2 to LCL4 are located in the insulating layer OL immediately above the insulating layer NL of the target to be reached.

As shown in FIG. 28B, an insulating layer 56 that covers the side walls and the bottom surfaces of the plurality of contact holes including the contact holes LCL2 to LCL4 is formed.

As shown in FIG. 28C, the insulating layer 56 is removed from the bottom surfaces of the plurality of contact holes including the contact holes LCL2 to LCL4, and the contact holes are caused to penetrate the insulating layer OL below insulating layer 56, so that the bottom surfaces of the contact holes are caused to reach the insulating layer NL of the target to be reached.

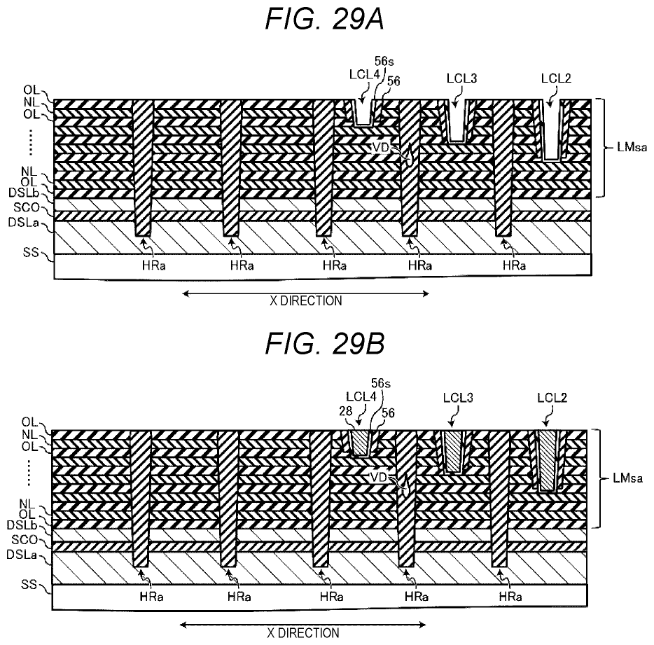

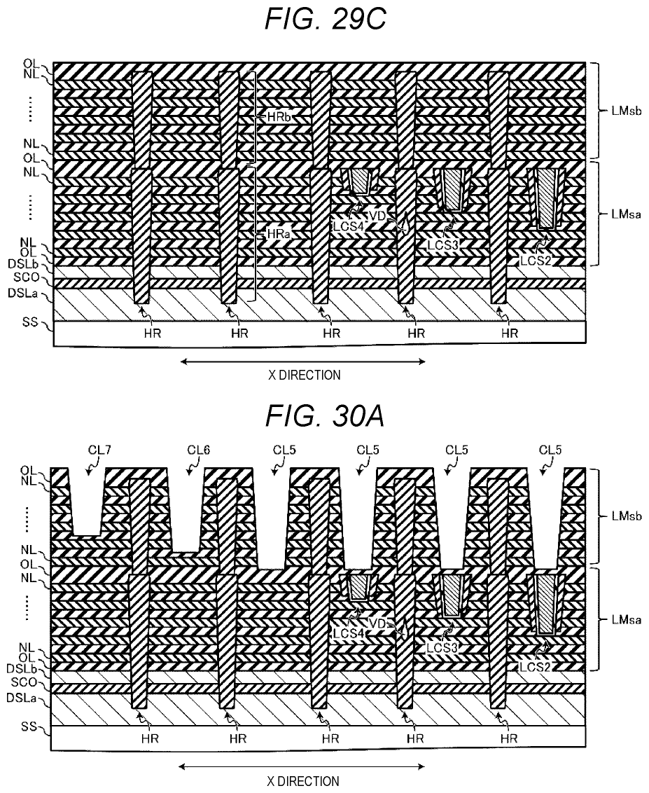

As shown in FIG. 29A, an insulating layer 56s that protects the insulating layer 56 formed on the side wall of the contact hole is formed on the side walls and the bottom surfaces of the plurality of contact holes including the contact holes LCL2 to LCL4.

As shown in FIG. 29B, the sacrificial layer 28 such as an amorphous silicon layer is formed in the plurality of contact holes including the contact holes LCL2 to LCL4. As a result, a plurality of columnar bodies including the columnar bodies LCS2 to LCS4 are formed.

As shown in FIG. 29C, the uppermost insulating layer OL of the stacked body LMsa is further stacked with a stacked body LMsb in which a plurality of insulating layers NL and OL are stacked. In addition, a plurality of the columnar portions HRb that penetrate the stacked body LMsb and are connected to the individual columnar portions HRa formed in the stacked body LMsa are formed. Accordingly, a plurality of columnar portions HR are formed.

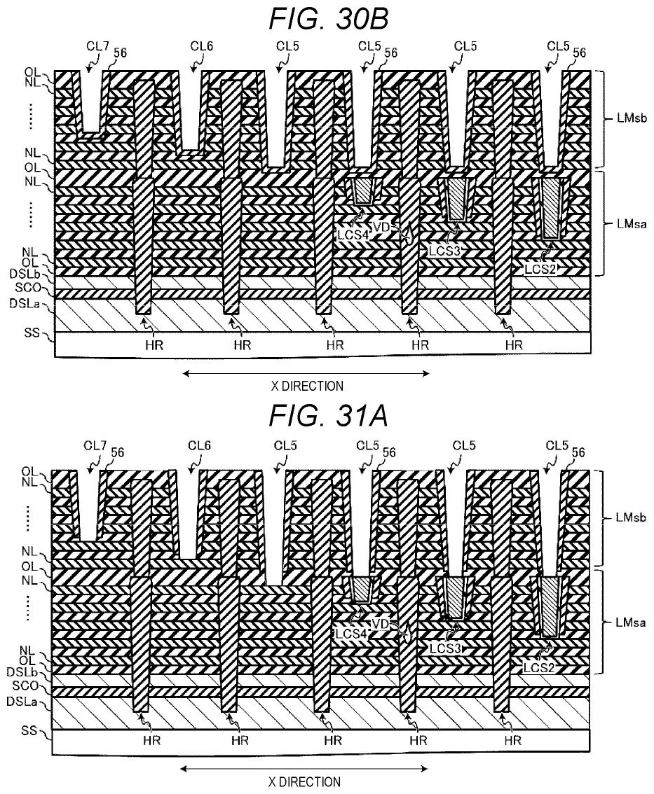

As shown in FIG. 30A, for example, a plurality of contact holes including the contact holes CL5, CL6, and CL7 are formed using the method shown in FIGS. 10A to 13B. The plurality of contact holes CL5 excluding the contact hole CL5 closest to the contact hole CL6 penetrate the stacked body LMsb at positions respectively corresponding to the columnar bodies LCS2 to LCS4, and the like formed in the stacked body LMsa. The contact holes CL5 excluding the contact hole CL5 closest to the contact hole CL6 set each of the insulating layers NL in the stacked body LMsa as a final target to be reached. The plurality of contact holes CL6 and CL7 and the contact hole CL5 closest to the contact hole CL6 set each of the insulating layers NL in the stacked body LMsb as a final target to be reached.

Even in the example of FIG. 30A, the plurality of contact holes including the contact hole CL5 closest to the contact hole CL6, contact hole CL6, and contact hole CL7 are formed with the insulating layer OL immediately above the insulating layer NL of the target to be reached, or the columnar bodies LCS2 to LCS4, and the like as the stopper layer. Therefore, in FIG. 30A, the bottom surfaces of the contact hole CL5 closest to the contact hole CL6, and the contact holes CL6 and CL7 are located in the insulating layer OL immediately above the insulating layer NL of the target to be reached. In addition, the remaining contact holes CL5 are located in the uppermost insulating layer OL of the stacked body LMsa without coming into contact with the upper end portions of the corresponding columnar bodies LCS2 to LCS4.

As shown in FIG. 30B, an insulating layer 56 that covers the side walls and the bottom surfaces of the plurality of contact holes including the contact holes CL5 to CL7 is formed.

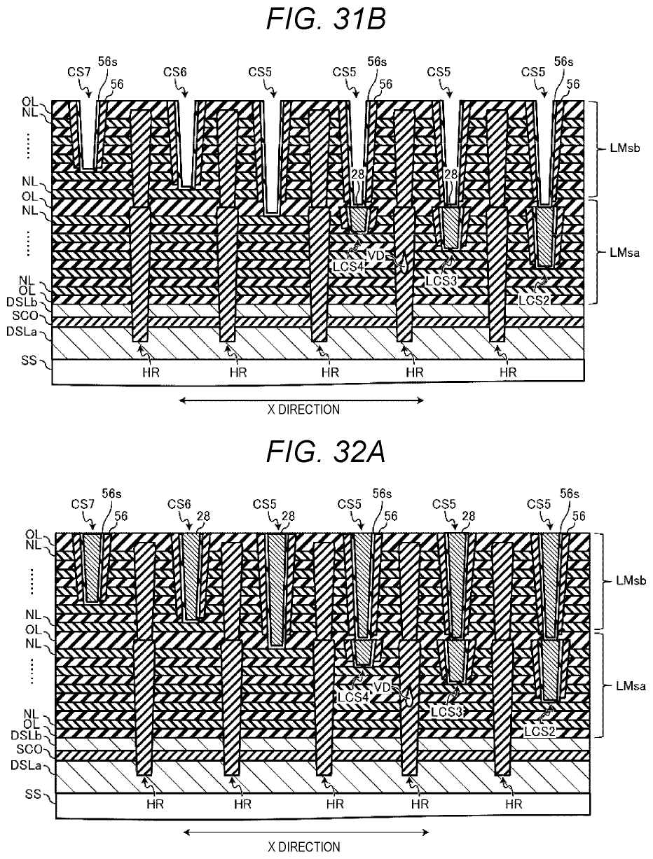

As shown in FIG. 31A, the insulating layer 56 is removed from the bottom surfaces of the plurality of contact holes including the contact holes CL5 to CL7, and the contact holes are caused to penetrate the insulating layer OL below insulating layer 56, so that the bottom surfaces of the contact holes are caused to reach the insulating layer NL of the target to be reached or the columnar bodies LCS2 to LCS4, and the like.

At this time, when the contact holes CL5 excluding the contact hole CL5 that sets the uppermost insulating layer NL of the stacked body LMsa as the target to be reached, reach the upper surface of the columnar bodies LCS2 to LCS4, and the like, etching does not proceed below the upper surface. The contact hole CL5 not connected to the columnar bodies LCS2 to LCS4, and the like has a bottom surface at a height position of the uppermost insulating layer NL of the stacked body LMsa, whereas the contact hole CL5 connected to the columnar bodies LCS2 to LCS4, and the like has the bottom surface at a position higher than the contact hole CL5 not connected to the columnar bodies LCS2 to LCS4, and the like.

As shown in FIG. 31B, an insulating layer 56s is formed on the side walls and the bottom surfaces of the plurality of contact holes including the contact holes CL5 to CL7.

At this time, among the plurality of contact holes CL5, in the contact hole CL5 connected to the columnar bodies LCS2 to LCS4, and the like, the insulating layer 56s on the bottom surface of the contact hole CL5 covers the sacrificial layer 28 that fills the columnar bodies LCS2 to LCS4, and the like. In addition, in order to protect the plurality of contact holes formed in the stacked body LMsb when proceeding with the subsequent processing, the sacrificial layer 28 is also formed in these contact holes.

Here, in the contact hole CL5 connected to the columnar bodies LCS2 to LCS4, and the like, when the insulating layer 56s is formed between the sacrificial layer 28 that fills the columnar bodies LCS2 to LCS4, and the like and the sacrificial layer 28 that fills the contact hole CL5, there is a possibility that the insulating layer 56s may be an obstacle when collectively removing the sacrificial layer 28 from the columnar bodies LCS2 to LCS4, and the like and the contact hole CL5 above the columnar bodies LCS2 to LCS4, and the like in the subsequent processing.

Therefore, as shown below, the insulating layer 56s is removed in advance from the bottom surface of the contact hole CL5 connected to the columnar bodies LCS2 to LCS4, and the like.

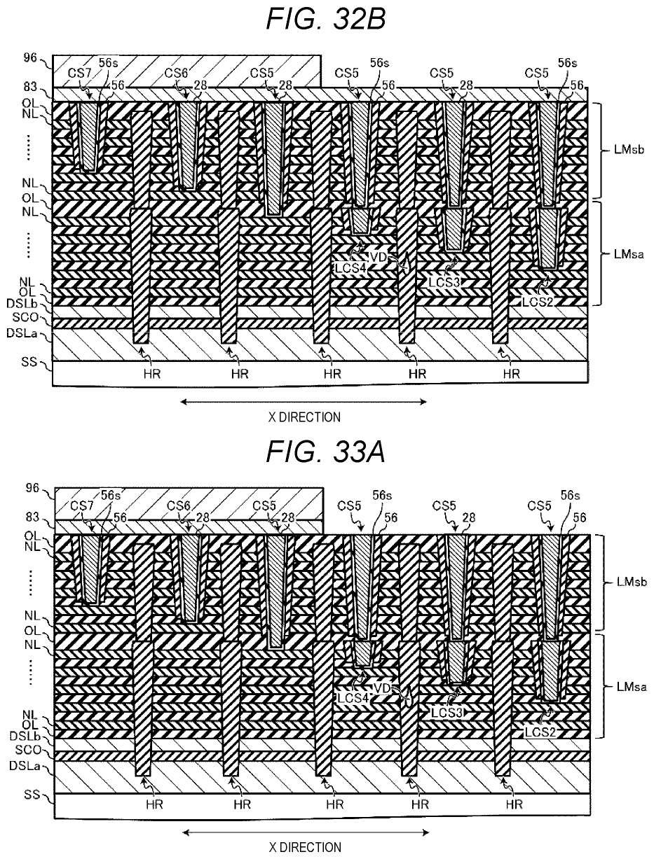

As shown in FIG. 32A, the sacrificial layer 28 such as an amorphous silicon layer fills the contact holes including the contact holes CL5 to CL7, and the like. An insulating layer 56s is interposed between the sacrificial layer 28 that fills the columnar bodies LCS2 to LCS4, and the like and the sacrificial layer 28 that fills the contact hole CL5, on the bottom surface of the contact hole CL5 connected to the columnar bodies LCS2 to LCS4, and the like.

As shown in FIG. 32B, a hard mask 83 that covers the upper surface of the stacked body LMsb is formed. In addition, a resist pattern 96 having an opening in a part thereof is formed on the hard mask 83. The resist pattern 96 covers a part of the contact hole via the hard mask 83. More specifically, the resist pattern 96 covers the contact holes including the contact holes CL6 and CL7, and the like, and the contact hole CL5 not connected to the columnar bodies LCS2 to LCS4, and the like.

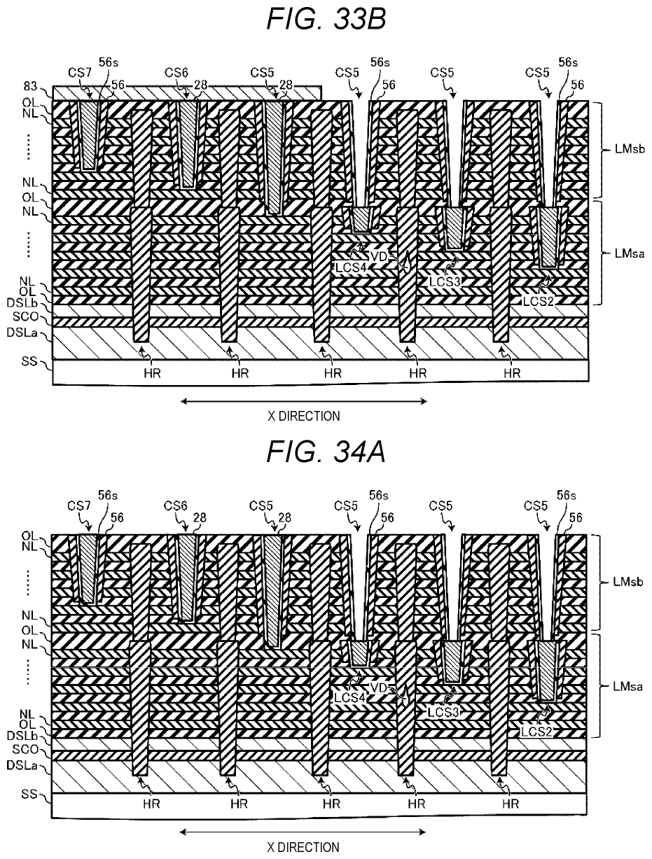

As shown in FIG. 33A, the hard mask 83 is processed using the resist pattern 96 as a mask. Accordingly, the sacrificial layer 28 connected to the columnar bodies LCS2 to LCS4, and the like and the contact hole CL5 are exposed.

As shown in FIG. 33B, the resist pattern 96 is removed by ashing using oxygen plasma or the like. In addition, the sacrificial layer 28 in the plurality of contact holes CL5 exposed from the hard mask 83 is removed. In addition, the insulating layer 56s is removed from the bottom surfaces of the plurality of contact holes CL5 from which the sacrificial layer 28 is removed.

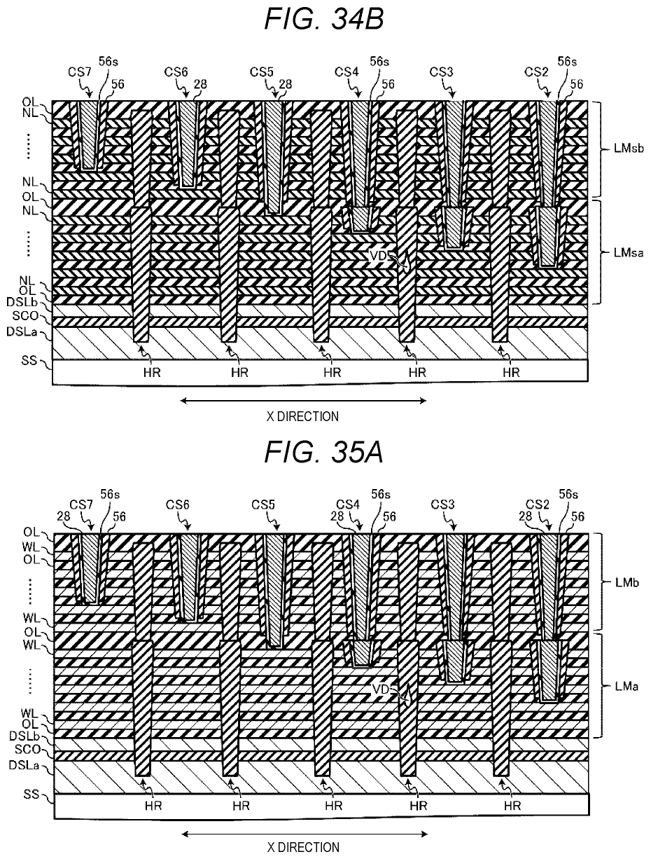

As shown in FIG. 34A, the hard mask 83 is removed.

As shown in FIG. 34B, by the processing of FIG. 33B described above, after the insulating layer 56s on the bottom surface is removed, the sacrificial layer 28 is formed again in the contact hole CL5 from which the sacrificial layer 28 has been removed. As a result, a plurality of columnar bodies including the columnar bodies CS2 to CS7 in which the sacrificial layer 28 that fills a plurality of contact holes including the contact holes CL5 to CL7 are formed.

FIG. 35A shows stacked bodies LMa and LMb after the replacement processing.

As shown in FIG. 35B, after the replacement processing of the stacked bodies LMa and LMb, the sacrificial layers 28 that fill the columnar bodies CS2 to CS7 are removed. As a result, the plurality of contact holes including the plurality of contact holes CL2 to CL7 are opened again. The plurality of contact holes CL2 to CL5 reach the plurality of word lines WL in the stacked body LMa. The plurality of contact holes CL6 and CL7 reach the plurality of word lines WL in the stacked body LMb.

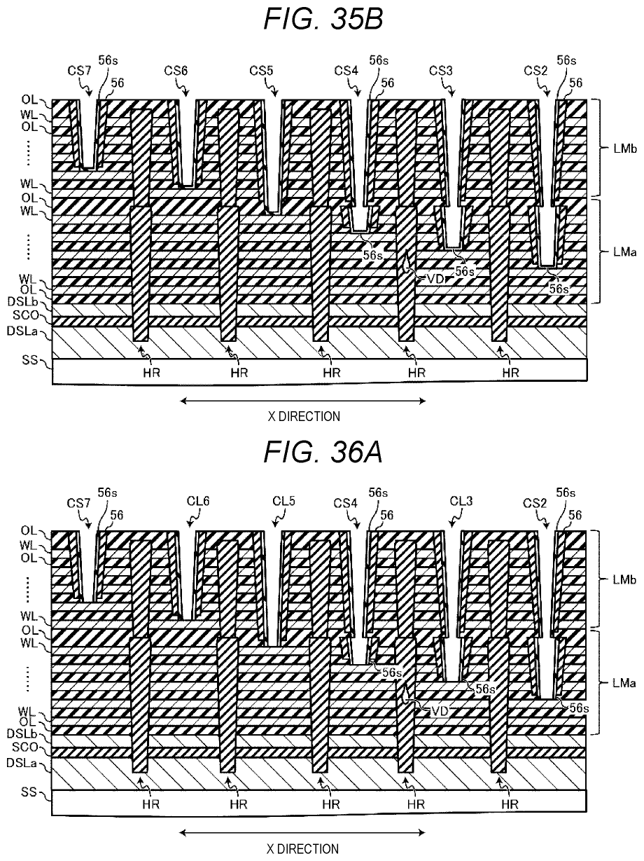

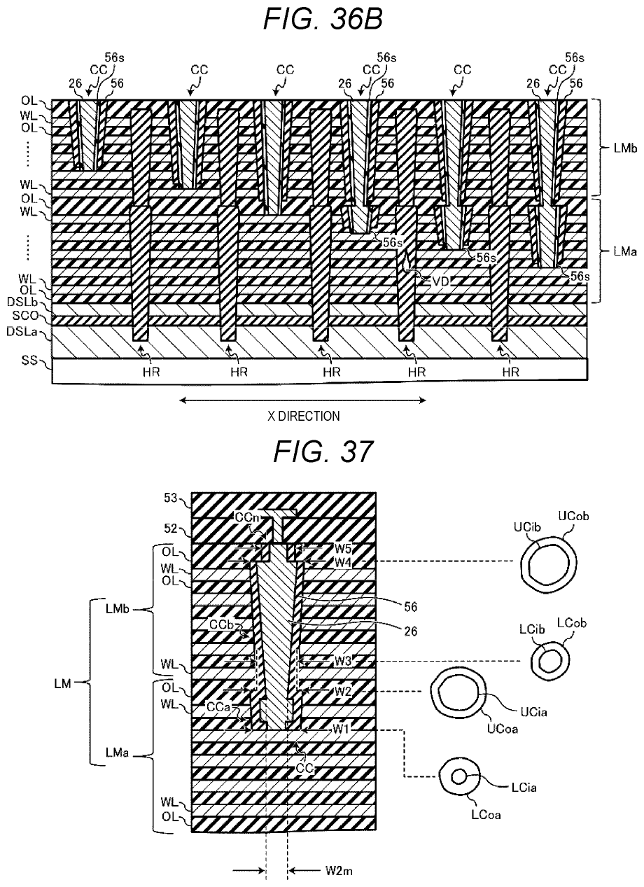

As shown in FIG. 36A, the insulating layer 56s is removed from the bottom surfaces of the plurality of contact holes CL2 to CL4, and the like reaching the plurality of word lines WL in the stacked body LMa.

In the example shown in FIG. 36A, for example, a narrow portion such as the through-hole THn of the above-described embodiment is not provided at the upper end portions of the plurality of contact holes including the contact holes CL2 to CL7. Meanwhile, the insulating layer 56s at the hole bottoms of the plurality of contact holes CL2 to CL4, and the like protects the insulating layer 56 when the sacrificial layer 28 or the like is removed, and is thinner than the insulating layer 56, for example.

Therefore, when the insulating layer 56s is removed from the hole bottoms of the plurality of contact holes CL2 to CL4, and the like, etching in the columnar portion HRx in the depth direction as described in the above-described comparative example is inhibited. Accordingly, it is possible to prevent a short circuit between the plurality of word lines WL.

As shown in FIG. 36B, the conductive layer 26 fills a plurality of contact holes including the contact holes CL2 to CL7 to form a plurality of contacts CC.

The subsequent processing is performed in the same manner as in the method for manufacturing the semiconductor storage device 1 of the above-described embodiment.

As described above, the formation and removal of the sacrificial layer 28 may be repeated a plurality of times in the plurality of contact holes including the contact holes LCL2 to LCL4, in the contact holes including the contact holes CL5 to CL7, and the like, and in the plurality of contact holes including the contact holes CL2 to CL7.

The above-described insulating layer 56s also has a function of protecting the insulating layer NL to which these contact holes are connected in the stacked bodies LMsb and LMsa before replacement from such processing in a plurality of times.

In addition, in the examples shown in FIGS. 28A to 36B, when replacing the stacked bodies LMsb and LMsa, the thick insulating layer 56 is previously removed from the bottom surfaces of the plurality of contact holes including the contact holes CL5 to CL7. Therefore, by forming the insulating layer 56s on the bottom surfaces of the contact holes CL5 to CL7, and the like, the sacrificial layer 28 that fills the contact holes CL5 to CL7, and the like can also be protected from the replacement processing of the stacked bodies LMsb and LMsa.

As described above, the insulating layer 56s that is thin with respect to the final insulating layer 56 may have a function of protecting various configurations such as the insulating layer 56 and the sacrificial layer 28 of the contact hole, and the insulating layer NL of the stacked bodies LMsb and LMsa in the processing each time.

As described above, the semiconductor storage device according to another modification example is manufactured.

In the examples shown in FIGS. 27 to 36B, the sacrificial layer 28 of the contact holes LCL2 to LCL4, and the like formed in the stacked body LMsa of the lower layer is not removed, and the sacrificial layers 28 are overlapped and formed in the contact holes CL5 to CL7, and the like formed in the stacked body LMsb of the upper layer, and the subsequent processing proceeds. However, as shown in FIG. 14A of the embodiment described above, after the sacrificial layer 28 of the contact holes LCL2 to LCL4, and the like is removed once, the sacrificial layer 28 may be collectively formed again in the contact holes CL5 to CL7, and the like and the contact holes LCL2 to LCL4, and the like formed in the stacked bodies LMsa and LMsb of the upper and lower layers.

When the sacrificial layer 28 is additionally formed in the contact holes CL5 to CL7, and the like on the sacrificial layer 28 that has been formed in the contact holes LCL2 to LCL4, and the like in the previous processing, an interface may be formed between the sacrificial layers 28. In addition, the upper surface of the sacrificial layer 28 formed in the contact holes LCL2 to LCL4, and the like may be modified or damaged by various processing. Therefore, the interface portions of the sacrificial layers 28 may be an obstacle when the sacrificial layers 28 are collectively removed later.

In the examples shown in FIGS. 27 to 36B, as in the above-described embodiment, the concerns can be dispelled by removing the sacrificial layer 28 of the contact holes LCL2 to LCL4, and the like once and collectively re-forming the sacrificial layer 28 in the contact holes CL5 to CL7, and the like and the contact holes LCL2 to LCL4, and the like. In this case, for example, after the processing shown in FIG. 34A, the sacrificial layer 28 is temporarily removed from the contact holes CL5 to CL7 including the contact hole CL5 not connected to the columnar bodies LCS2 to LCS4, and the like and the columnar bodies LCS2 to LCS4, and the like to which the contact hole CL5 is connected, and then the sacrificial layer 28 can be collectively formed in the contact hole formed in the stacked bodies LMsb and LMsa of the upper and lower layers by the processing shown in FIG. 34B.

In addition, in the examples shown in FIGS. 27 to 36B, the contact CC that connects to the word line WL of the uppermost layer of the stacked body LMa reaches the height position of the word line WL to be connected to the lower end portion of the contact portion CCb to connect to the word line WL without having the contact portion CCa. However, the contact CC, which connects to the word line WL of the uppermost layer of the stacked body LMa, may have both the contact portions CCa and CCb, and may be connected to the word line WL at the lower end portion of the contact portion CCa.

In this case, in the processing shown in FIG. 29B and the like, in addition to the columnar bodies LCS2 to LCS4, and the like, a columnar body having the insulating layers 56 and 56s and the sacrificial layer 28 can be formed in the uppermost insulating layer OL of the stacked body LMsa. In addition, in the processing shown in FIG. 31A, the contact hole CL5 is processed to reach the columnar body formed in the uppermost insulating layer OL, as in the other contact holes CL5 connected to the columnar bodies LCS2 to LCS4, and the like.

Accordingly, in the processing shown in FIG. 31A, for example, when the insulating layer 56 is removed from the bottom surface of the contact holes CL5 to CL7, and the like, the height positions of the bottom surfaces of all the contact holes CL5 can be aligned. Therefore, all the contact holes CL5 can be formed without performing excessive overetching on the other contact holes CL5 connected to the columnar bodies LCS2 to LCS4, and the like in order to cause the contact hole CL5 not connected to the columnar body to reach the uppermost insulating layer NL of the stacked body LMsa. Therefore, for example, it is possible to prevent the surface of the sacrificial layer 28 of the columnar bodies LCS2 to LCS4, and the like from being damaged due to excessive overetching.

In addition, in the examples shown in FIGS. 27 to 36B, when forming the contact holes LCL2 to LCL4, CL5 to CL7, and the like, the insulating layer OL immediately above the insulating layer NL of the target to be reached is used as the stopper layer. Meanwhile, even in the semiconductor storage device of another modification example, as shown in FIGS. 4A to 6C and FIGS. 10A to 13B of the above-described embodiment, the insulating layer NL itself of the target to be reached may be used as the stopper layer to form the contact hole from the beginning.

In addition, in the examples shown in FIGS. 27 to 36B, the through-holes THn are not provided at the upper end portions of the plurality of contact holes including the contact holes CL2 to CL7. However, the through-holes THn may be provided in at least some of the plurality of contact holes, and the finally obtained contact CC may have the neck portion CCn as in the embodiment described above.

In addition, in the above-described embodiment, the narrow portion such as the lower end portion of the contact portion CCb, which is connected to the contact portion CCa, the neck portion CCn, and the like is provided in the contact CC. As a result, when the insulating layer 56 is removed from the bottom surface of the contact hole, a part of the insulating layer 56 may remain at the outer edge portion of the bottom surface of the contact hole. The example is shown in FIG. 37.

FIG. 37 is a sectional view showing an example of the dimensions of each portion of a contact CC connected to a predetermined word line WL in a semiconductor storage device according to another modification example of the embodiment.

As shown in FIG. 37, at the upper end portion of the contact portion CCb having the diameter W4, the shape UCib of the inner wall surface of the insulating layer 56 on the side wall of the contact portion CCb is similar to the shape UCob of the outer wall surface, the shape UCib being smaller than the shape UCob of the outer wall surface by the thickness of the insulating layer 56. Here, the outer wall surface of the insulating layer 56 is a surface of the insulating layer 56 facing the outside of the contact portion CCb, and is a surface in contact with the word line WL and the insulating layer OL of the stacked body LMb. In addition, the inner wall surface of the insulating layer 56 is a surface of the insulating layer 56 facing the inside of the contact portion CCb, and is a surface in contact with the conductive layer 26 of the contact portion CCb.

In addition, even at the lower end portion of the contact portion CCb having the diameter W3, the shape LCib of the inner wall surface of the insulating layer 56 on the side wall of the contact portion CCb is similar to the shape LCob of the outer wall surface, the shape LCib being smaller than the shape LCob of the outer wall surface by the thickness of the insulating layer 56.

In addition, even at the upper end portion of the contact portion CCa having the diameter W2, the shape UCia of the inner wall surface of the insulating layer 56 on the side wall of the contact portion CCa is similar to the shape UCoa of the outer wall surface, the shape UCia being smaller than the shape UCoa of the outer wall surface by the thickness of the insulating layer 56.

Meanwhile, in the example shown in FIG. 37, since the lower end portion of the contact portion CCb above the contact portion CCa is a narrow portion, a part of the insulating layer 56 remains at the outer edge portion of the bottom surface of the contact portion CCa. Therefore, at the lower end portion of the contact portion CCa having the diameter W1, with respect to the shape LCoa of the outer wall surface of the insulating layer 56 on the side wall of the contact portion CCa, the shape LCia of the inner wall surface has a smaller diameter than the shape LCoa of the outer wall surface by the thickness of the insulating layer 56 or more.

The remaining of the insulating layer 56 on the bottom surface of the contact portion CCa and the shape LCia of the inner wall surface are due to the shielding effect of the lower end portion of the contact portion CCb, which is a narrow portion, when the insulating layer 56 is etched and removed. Therefore, the shape LCia of the inner wall surface may not be similar to the shape LCoa of the outer wall surface, but may be a shape close to a similar shape to the shape UCib of the inner wall surface of the insulating layer 56 of the lower end portion of the contact portion CCb. More strictly, it is considered that the shape similar to shape of the inner wall surface of the insulating layer 56 having the diameter W2m in which the inner diameter of the insulating layer 56 is the narrowest is extremely close to the shape LCia of the inner wall surface in the example of FIG. 27, in the vicinity of the upper end portion of the contact portion CCa located below the stacking direction of the stacked body LMa from the lower end portion of the contact portion CCb having the diameter W3 by the layer thickness of the insulating layer 56.

Meanwhile, it can be said that the lower end portion of the contact portion CCb and the portion of the insulating layer 56 in which the inner diameter is the narrowest are sufficiently close to each other, and that the shape UCib of the inner wall surface of the insulating layer 56 at the lower end portion of the contact portion CCb and the shape of the inner wall surface of the insulating layer 56 at the portion of the insulating layer 56 in which the inner diameter is the narrowest substantially coincide with each other.

In addition, the influence of such a shielding effect is more significant on the contact portion CCa connected to the word line WL on the upper layer side of the stacked body LMa among the plurality of contact portions CCa. This is because the bottom surface of the contact portion CCa is located closer to the lower end portion of the contact portion CCb, which is the narrower portion.

In addition, the influence of such a shielding effect may also be generated on the bottom surface of the contact CC, which is connected to the word line WL of the stacked body LMb and has the neck portion CCn that is a narrow portion above. Therefore, a part of the insulating layer 56 may also remain at the outer edge portion of the bottom surface of these contact CC. Even in this case, the influence of such a shielding effect is more significant on the contact CC connected to the word line WL on the upper layer side of the stacked body LMb. This is because the bottom surface of the contact CC is located closer to the neck portion CCn, which is the narrow portion.

When the insulating layer 56 remains on the bottom surface of the contact CC, the area where the conductive layer 26 of the contact CC and the word line WL to be connected are conducted is slightly reduced. Meanwhile, the influence of this on the electrical connection between the contact CC and the word line WL is not significant, and the increase in the electric resistance at the connection portion between the contact CC and the word line WL is also within a range that may be ignored.

In addition, in the above-described embodiment, the contact regions ER are disposed at both end portions of the stacked body LM in the X direction. However, the position of the contact region ER in the stacked body LM is not limited thereto. The contact region ER may be disposed, for example, at the central portion of the stacked body LM, and in this case, for example, the memory region MR can be disposed at both end portions of the stacked body LM.

In addition, in the above-described embodiment, the pillar PL is connected to the source line SL on the side surface of the channel layer CN, but the present disclosure is not limited thereto. For example, the pillar may be configured such that the memory layer on the bottom surface of the pillar is removed and the pillar connects to the source line at the lower end portion of the channel layer.

In addition, in the above-described embodiment, the columnar portion HR is formed of only the insulating layer 54. Meanwhile, the columnar portion HR may have the same layer structure as the pillar PL, for example. Even in this case, at least a part of the multilayered columnar portion HR may be a layer that is easily etched together with the insulating layer 56 of the hole bottom, and by applying the above configuration, it is possible to obtain the effect of preventing the short circuit between the plurality of word lines WL.

In addition, in the above-described embodiment, the insulating layers NL and OL are stacked twice to form the stacked body LM having the 2-tier structure including the stacked bodies LMa and LMb. However, the stacked body may have a structure of 3-tier or more. By increasing the number of tiers, the number of stacked layers of the word line WL can be further increased.

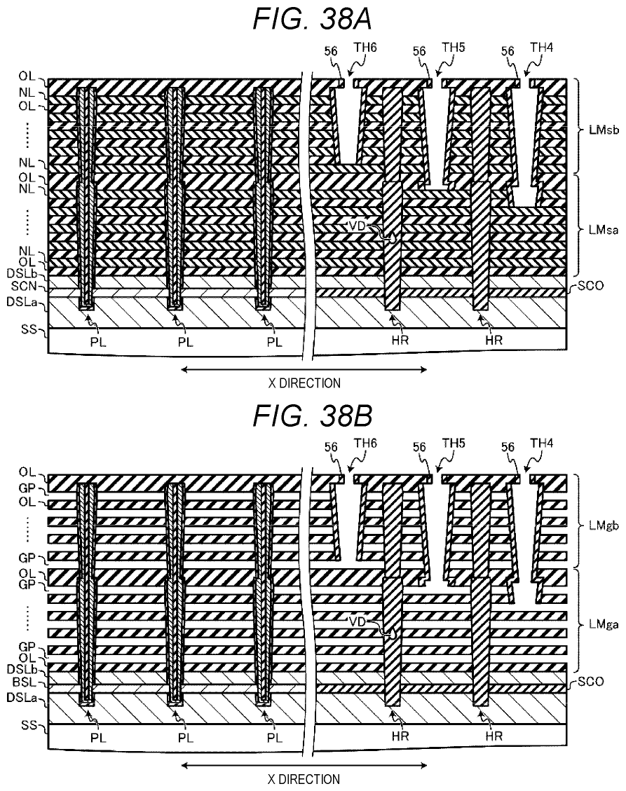

In addition, in the above-described embodiment, the replacement processing of the stacked bodies LMsa and LMsb is performed through the slit ST. However, the replacement processing may be performed using the contact hole together with the slit ST. The example of this case is shown in FIGS. 38A and 38B.

FIGS. 38A to 38B are sectional views along the X direction showing a part of the procedure of the method for manufacturing a semiconductor storage device according to another modification example of the embodiment.

As shown in FIG. 38A, before the replacement processing of the stacked bodies LMsa and LMsb, processing up to removing the insulating layer 56 on the bottom surface of the contact holes TH4 to TH6, and the like is completed.

Thereafter, as shown in FIG. 19A, a removal liquid for the insulating layer NL, such as hot phosphoric acid, is caused to flow into the stacked bodies LMsa and LMsb through the slit ST.

As shown in FIG. 38B, the removal liquid for the insulating layer NL, such as hot phosphoric acid, flows into the individual insulating layer NL to be connected from the contact holes TH4 to TH6, and the like from which the insulating layer 56 on the bottom surface is removed at this time. As a result, the insulating layer NL is removed.

Thereafter, in the same manner, the raw material gas of the conductive material such as tungsten or molybdenum is injected into the stacked bodies LMga and LMgb from both the slit ST and the contact holes TH4 to TH6, and the like. As a result, a plurality of word lines WL are formed.

As described above, by using the slit ST and the contact holes TH4 to TH6, and the like in combination, the replacement processing of the stacked bodies LMsa and LMsb can be performed more efficiently.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first stacked body in which a plurality of first conductive layers and a plurality of first insulating layers are alternately stacked in a stacking direction;
a second stacked body that is disposed above the first stacked body and in which a plurality of second conductive layers and a plurality of second insulating layers are alternately stacked in the stacking direction;
a first pillar that extends in the first and second stacked bodies in the stacking direction and has a semiconductor layer and a memory layer that covers a side wall of the semiconductor layer; and
a first contact that extends in the first and second stacked bodies in the stacking direction and is connected to one first conductive layer of the plurality of first conductive layers,
wherein the first contact has
a first portion that extends in the first stacked body and is connected at a lower end portion thereof to the one first conductive layer,
a second portion that extends in the second stacked body and is connected to an upper end portion of the first portion, the second portion having a cross-sectional area at a lower end portion thereof as viewed from the stacking direction that is smaller than a cross-sectional area at the upper end portion of the first portion as viewed from the stacking direction, and
a third conductive layer that continuously extends in the first and second portions in the stacking direction.

2. The semiconductor storage device according to claim 1,
wherein the first and second portions are connected to each other in an uppermost first insulating layer among the plurality of first insulating layers of the first stacked body.

3. The semiconductor storage device according to claim 2,
wherein the upper end portion of the first portion is located in the uppermost first insulating layer and the lower end portion of the second portion is located in the uppermost first insulating layer.

4. The semiconductor storage device according to claim 1,
wherein the first contact further has a third portion that is connected to an upper end portion of the second portion, the third portion having a cross-sectional area at a lower end portion thereof as viewed from the stacking direction that is smaller than a cross-sectional area at the upper end portion of the second portion as viewed from the stacking direction.

5. The semiconductor storage device according to claim 4,
wherein the third conductive layer continuously extends in the first, second, and third portions in the stacking direction.

6. The semiconductor storage device according to claim 4, further comprising:
a second contact that that extends in the second stacked body in the stacking direction and is connected to one second conductive layer of the plurality of second conductive layers, wherein the second contact has
a fourth portion that extends in the second stacked body and is connected at a lower end portion thereof to the one second conductive layer,
a fifth portion that is connected to an upper end portion of the fourth portion, the fifth portion having a cross-sectional area at a lower end portion thereof as viewed from the stacking direction that is smaller than a cross-sectional area at the upper end portion of the fourth portion as viewed from the stacking direction
a fourth conductive layer that continuously extends in the fourth and fifth portions in the stacking direction.

7. The semiconductor storage device according to claim 6,
wherein the third conductive layer and the fourth conductive layer are made of the same conductive material.

8. The semiconductor storage device according to claim 6, further comprising:
a plurality of second pillars that extend in the first and second stacked bodies in the stacking direction and have a pitch narrower than a maximum value of a cross-sectional area in the first contact as viewed from the stacking direction,
wherein the second pillars are arranged in a region where the first and second contacts are arranged, and the first pillar and a plurality of third pillars having the same structure as the first pillar are arranged in a region different from where the first and second contacts and the second pillars are arranged.

9. The semiconductor storage device according to claim 8,
wherein at least one of the first and second contacts is disposed at a position overlapping one of the second pillars when viewed from the stacking direction.

10. The semiconductor storage device according to claim 8, wherein the first pillar and the third pillars are arranged at a higher density than the second pillars.

11. A semiconductor storage device comprising:
a stacked body in which a plurality of conductive layers and a plurality of insulating layers are alternately stacked in a stacking direction;
a pillar that extends in the stacked body in a stacking direction of the stacked body and has a semiconductor layer and a memory layer that covers a side wall of the semiconductor layer; and
a conductive contact that extends in the stacked body in the stacking direction and is connected to one of the plurality of conductive layers,
wherein the conductive contact has a central portion that is in an insulating layer, which is one of the plurality of insulating layers near a center of the stacked body in the stacking direction, in which a cross-sectional area thereof as viewed from the stacking direction is discontinuously changed, and
the cross-sectional area of the central portion is smaller on an upper surface side of the insulating layer than on a lower surface side of the insulating layer.

12. The semiconductor storage device according to claim 11, wherein the conductive contact further has a neck portion at an upper end thereof, the neck portion having a cross-sectional area as viewed from the stacking direction, that is smaller than a cross-sectional area at an upper portion of the conductive contact that is below the neck portion, as viewed from the stacking direction.

13. The semiconductor storage device according to claim 12, wherein the insulating layer has the largest thickness among the insulating layers stacked in the stacked body.

14. The semiconductor storage device according to claim 13, further comprising:
a plurality of first pillars arranged in a first region at a first density, each of the first pillars extending in the stacked body in the stacking direction and having a semiconductor layer and a memory layer that covers a side wall of the semiconductor layer; and
a plurality of second pillars arranged in a second region at a second density that is lower than the first density, each of the second pillars extending in the stacked body in the stacking direction,
wherein the conductive contact is also arranged in the second region and is in contact with one of the second pillars.

15. The semiconductor storage device according to claim 11, further comprising:
an insulating layer that electrically isolates the conductive contact from the conductive layers in the stacked body except for the one conductive layer that the conductive contact is connected to.

16. A method for manufacturing a semiconductor storage device, the method comprising:
forming a first stacked body in which a plurality of first insulating layers and a plurality of second insulating layers are alternately stacked in stacking direction;
forming a first memory hole that extends in the first stacked body in the stacking direction of the first stacked body;
forming a first contact hole that extends in the first stacked body in the stacking direction and reaches one of the plurality of first insulating layers;
forming a second stacked body in which a plurality of third insulating layers and a plurality of fourth insulating layers are alternately stacked above the first stacked body in the stacking direction;
forming a second memory hole that extends in the second stacked body in the stacking direction and is connected to the first memory hole;
forming a second contact hole that extends in the second stacked body in the stacking direction and is connected to the first contact hole at a lower end portion thereof, wherein the lower end portion of the second contact hole has a cross-sectional area as viewed from the stacking direction that is smaller than a cross-sectional area of an upper end portion of the first contact hole as viewed from the stacking direction; and
filling the first and second contact holes with a first conductive layer that continuously extends in the first and second contact holes.

17. The method for manufacturing a semiconductor storage device according to claim 16, further comprising:
prior to filling the first and second contact holes with the first conductive layer, forming a fifth insulating layer that covers side walls of the first and second contact holes and a bottom surface of the first contact hole, and removing the fifth insulating layer from the bottom surface of the first contact hole.

18. The method for manufacturing a semiconductor storage device according to claim 17, further comprising:
forming a first through-hole that is connected to the second contact hole, from above the second contact hole, wherein
a lower end portion of the first through-hole has a cross-sectional area as viewed from the stacking direction that is smaller than a cross-sectional area of an upper end portion of the second contact hole as viewed from the stacking direction.

19. The method for manufacturing a semiconductor storage device according to claim 18, wherein the fifth insulating layer is removed from the bottom surface of the first contact hole by performing ion bombardment through the first through-hole.

20. The method for manufacturing a semiconductor storage device according to claim 18, further comprising:
forming a third contact hole that extends in the second stacked body and reaches one of the plurality of third insulating layers; and
forming a second through-hole that is connected to the third contact hole, from above the third contact hole, wherein
a lower end portion of the second through-hole has a cross-sectional area as viewed from the stacking direction that is smaller than a cross-sectional area of an upper end portion of the third contact hole as viewed from the stacking direction.
